(19) United States
(12) Patent Application Publication
(10) Pub. No.: US 2016/0164537 A1
(43) Pub. Date: Jun. 9, 2016

(54) METHOD AND APPARATUS FOR PARALLEL CONCATENATED LDPC CONVOLUTIONAL CODES ENABLING POWER-EFFICIENT DECODERS

(71) Applicant: Samsung Electronics Co., Ltd., Suwon-si (KR)

(72) Inventors: Eran Pisek, Plano, TX (US); Shadi Abu-Surra, Plano, TX (US)

(21) Appl. No.: 14/827,150

(22) Filed: Aug. 14, 2015

Related U.S. Application Data
(60) Provisional application No. 62/147,410, filed on Apr. 14, 2015.
(60) Provisional application No. 62/089,035, filed on Dec. 8, 2014.

(51) Int. Cl. H03M 13/11; H03M 13/29; H03M 13/39

(52) U.S. Cl. CPC H03M 13/116; H03M 13/3944; H03M 13/2909

(57) ABSTRACT

A method of encoding includes receiving input systematic data including an input group (x_{z}(n)) of Z systematic bits. The method includes generating an LDPC base code using the input group (x_{z}(n)). The LDPC base code is characterized by a row weight (Wr), a column weight (Wc), and a first level lifting factor (Z). The method includes transforming the LDPC base code into a Trellis-based Quasi-Cyclic LDPC (TQC-LDPC) convolutional code. The method includes generating a Parallel Concatenated TQC-LDPC convolutional code in a form of an H-matrix including a systematic submatrix (H_{sys}) of the input systematic data and a parity check submatrix (Hₚₐᵣ) of parity check bits, wherein the Hₚₐᵣ includes a column of Z-group parity bits. The method includes concatenating the Hₚₐᵣ with each column of systematic bits, wherein the Hₚₐᵣ includes J parity bits per systematic bit.

### CROSS-REFERENCE TO RELATED APPLICATION(S) AND CLAIM OF PRIORITY

The present application claims priority to U.S. Provisional Patent Application Ser. No. 62/089,035, filed Dec. 8, 2014, entitled “METHOD AND APPARATUS OF JOINT SECRET ADVANCED LDPC CRYPTCODING” and U.S. Provisional Patent Application Ser. No. 62/147,410, filed Apr. 14, 2015, entitled “QC-MAP DECODER ARCHITECTURE.” The contents of the above-identified patent documents are incorporated herein by reference.

### TECHNICAL FIELD

The present application relates generally to channel coding, and more specifically, to a method and apparatus for parallel concatenated low density parity check (LDPC) convolutional codes enabling power-efficient decoders.

### BACKGROUND

In information theory, a low-density parity-check (LDPC) code is an error correcting code for transmitting a message over a noisy transmission channel. LDPC codes are a class of linear block codes. While LDPC and other error correcting codes cannot guarantee perfect transmission, the probability of lost information can be made as small as desired. LDPC was the first code to allow data transmission rates close to the theoretical maximum known as the Shannon Limit. LDPC codes can perform with 0.0045 dB of the Shannon Limit. LDPC was impractical to implement when developed in 1963. Turbo codes, discovered in 1993, became the coding scheme of choice in the late 1990s. Turbo codes are used for applications such as deep-space satellite communications. LDPC requires complex processing, but is the most efficient scheme discovered as of 2007.

Capacity approaching LDPC codes have large block sizes (>>1000 bits) in order to realize efficiency. Block LDPC codes can be obtained in only a few block sizes such that the granularity of information being processed is coarse. The LDPC block codes are aligned to an orthogonal frequency-division multiplexing (OFDM) symbol. Accordingly, large block size codes reduce the flexibility of a system and significantly increase the latency.

Convolutional LDPC codes employ a complex design that is not quasi-cyclic. Convolutional LDPC codes employ complex decoding processes with a high number of iterations. Accordingly, convolutional LDPC codes are characterized by a low data rate and belief propagation only.

Trellis-based quasi-cyclic (TQC) LDPC convolutional codes provide a fine granularity, such as a lifting factor level (Z-level) of granularity. Example lifting factors include 42 bits or 27 bits. However, TQC-LDPC convolutional codes are non-capacity approaching, as such, the normalized signal to noise ratio (E_{b}/N₀) is approximately 2.5 decibels (dB) at a bit error rate (BER) of 10⁻⁵. The normalized signal to noise ratio is defined as the energy per bit (E_{b}) as compared to noise spectral density (N₀).

### SUMMARY

This disclosure provides an apparatus and method for Parallel-concatenated Trellis-based QC-LDPC Convolutional Codes enabling power efficient decoders.

In a first embodiment, a method of encoding includes receiving input systematic data including an input group (x_{z}(n)) of Z systematic bits. The method includes generating a Low Density Parity Check (LDPC) base code using the input group (xz(n)). The LDPC base code is characterized by a row weight (Wr), a column weight (Wc), and a first level lifting factor (Z). The method includes transforming the LDPC base code into a Trellis-based Quasi-Cyclic LDPC (TQC-LDPC) convolutional code. The method includes generating, by Trellis-based Quasi-Cyclic LDPC Recursive Systematic Convolutional (QC-RSC) encoder processing circuitry using the TQC-LDPC convolutional code, a Parallel Concatenated Trellis-based Quasi-Cyclic LDPC (PC-LDPC) convolutional code in a form of an H-matrix including a systematic submatrix (Hsys) of the input systematic data and a parity check submatrix (Hpar) of parity check bits, wherein the Hpar includes a column of Z-group parity bits. The method includes concatenating the Hpar with each column of systematic bits, wherein the Hpar includes J parity bits per systematic bit.

In a second embodiment, an encoder includes Trellis-based Quasi-Cyclic LDPC Recursive Systematic Convolutional (QC-RS C) encoder processing circuitry configured to: receive input systematic data including an input group (xz(n)) of Z systematic bits. The QC-RSC encoder processing circuitry is configured to: generate a Low Density Parity Check (LDPC) base code using the input group (xz(n)). The LDPC base code is characterized by a row weight (Wr), a column weight (Wc), and a first level lifting factor (Z). The QC-RSC encoder processing circuitry is configured to: transform the LDPC base code into a Trellis-based Quasi-Cyclic LDPC (TQC-LDPC) convolutional code. The QC-RSC encoder processing circuitry is configured to: generate a Parallel Concatenated Trellis-based Quasi-Cyclic LDPC (PC-LDPC) convolutional code in a form of an H-matrix. The H-matrix includes a systematic submatrix (Hsys) of the input systematic data and a parity check submatrix (Hpar) of parity check bits, wherein the Hpar includes a column of Z-group parity bits. he QC-RSC encoder processing circuitry is configured to: concatenate the Hpar with each column of systematic bits, wherein the Hpar includes J parity bits per systematic bit.

In a third embodiment, a decoder includes Trellis-based Quasi-Cyclic Low Density Parity Check (TQC-LDPC) Maximum A posteriori Probability (MAP) decoder processing circuitry configured to: receive a Parallel Concatenated Trellis-based Quasi-Cyclic LDPC (PC-LDPC) convolutional code in a form of an H-matrix. The H-matrix includes a systematic submatrix (Hsys) of the input systematic data and a parity check submatrix (Hpar) of parity check bits. The PC-LDPC convolutional code is characterized by a lifting factor (Z), the Hpar includes a column of Z-group parity bits concatenated with each column of systematic bits. The Hpar includes J parity bits per systematic bit. The TQC-LDPC MAP decoder processing circuitry is configured to: decode the PC-LDPC convolutional code into and a group (xz(n)) of Z systematic bits by, for each Z-row of the PC-LDPC convolutional code: (i) determining, from the PC-LDPC convolutional code, a specific quasi-cyclical domain of the Z-row that is different from any other quasi-cyclical domain of another Z-row of the PC-LDPC convolutional code; (ii) quasi-cyclically shifting the bits of the Z-row by the specific quasi-cyclical domain; (iii) performing Z parallel MAP decoding processes on the shifted bits of the Z-row; and (iv) unshifting the parallel decoded bits of the Z-row by the specific quasi-cyclical domain, yielding the group (xz(n)) of Z systematic bits.

Other technical features may be readily apparent to one skilled in the art from the following figures, descriptions, and claims.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example wireless network according to this disclosure;

FIGS. 2A and 2B illustrate example wireless transmit and receive paths according to this disclosure;

FIG. 3 illustrates an example user equipment according to this disclosure;

FIG. 4 illustrates an example enhanced NodeB according to this disclosure;

FIG. 5 illustrates a Parallel Concatenated Trellis-based Quasi-Cyclic Low Density Parity Check Recursive Systematic Convolutional (QC-RSC) encoder according to this disclosure;

FIG. 6 illustrates a Trellis-based Quasi-Cyclic Low Density Parity Check (TQC-LDPC) Maximum A posteriori Probability (MAP) decoder according to this disclosure;

FIG. 7A illustrates a PC-LDPC encoding process according to this disclosure;

FIG. 7B illustrates a PC-LDPC decoding process according to this disclosure;

FIG. 8 illustrates the QC-RSC encoder of FIG. 5 in more detail according to this disclosure;

FIG. 9 illustrates a Recursive Systematic Convolutional (RSC) encoder according to this disclosure;

FIG. 10 illustrates an example of a Spatially-coupled Low Density Parity Check (SC-LDPC) base code according to this disclosure;

FIG. 11 illustrates another example of an SC-LDPC base code according to this disclosure;

FIG. 12 illustrates a transformation of an SC-LDPC base code to an SC-LDPC code, to a serialized SC-LDPC code, to a concatenated SC-LDPC encoding structure according to this disclosure;

FIGS. 13A and 13B (together referred to as FIG. 13) illustrates a process of generating a column of parity bits for a Parallel Concatenated Trellis-based Quasi-Cyclic Low Density Parity Check (PC-LDPC) convolutional code having an output rate of ½ from a concatenated SC-LDPC encoding structure having a separation of systematic bits from parity bits according to embodiments of this disclosure;

FIG. 14 illustrates a process of generating a column of parity bits for a modified TQC-LDPC convolutional code having an output rate of ⅓ according to embodiments of this disclosure;

FIG. 15 illustrates a process of puncturing by applying a puncturing pattern to the modified TQC-LDPC convolutional code having an output rate of ½ of FIG. 14 according to embodiments of this disclosure;

FIG. 16 illustrates a process of reducing periodicity while generating a column of parity bits for an example modified TQC-LDPC convolutional code having an output rate of ⅓ according to embodiments of this disclosure;

FIG. 17 illustrates a process of process of reducing periodicity and puncturing by applying a puncturing pattern to the modified TQC-LDPC convolutional code having an output rate of ⅓ of FIG. 16 according to embodiments of this disclosure;

FIG. 18 illustrates a Dual-Step PC-LDPC convolutional code according to embodiments of this disclosure;

FIG. 19 illustrates the TQC-LDPC MAP decoder of FIG. 6 in more detail according to this disclosure;

FIG. 20 illustrates a Normalized Complexity Comparison for a QC-MAP having an output rate of ½ and a bit error rate (BER) of 10⁻⁵ according to this disclosure;

FIG. 21 illustrates a comparison table for QC-MAP hardware implementation including values corresponding to the graph in FIG. 20 according to this disclosure; and

FIG. 22 illustrates an example Z Maximum A posteriori Probability (Z-MAP) decoder according to this disclosure.

### DETAILED DESCRIPTION

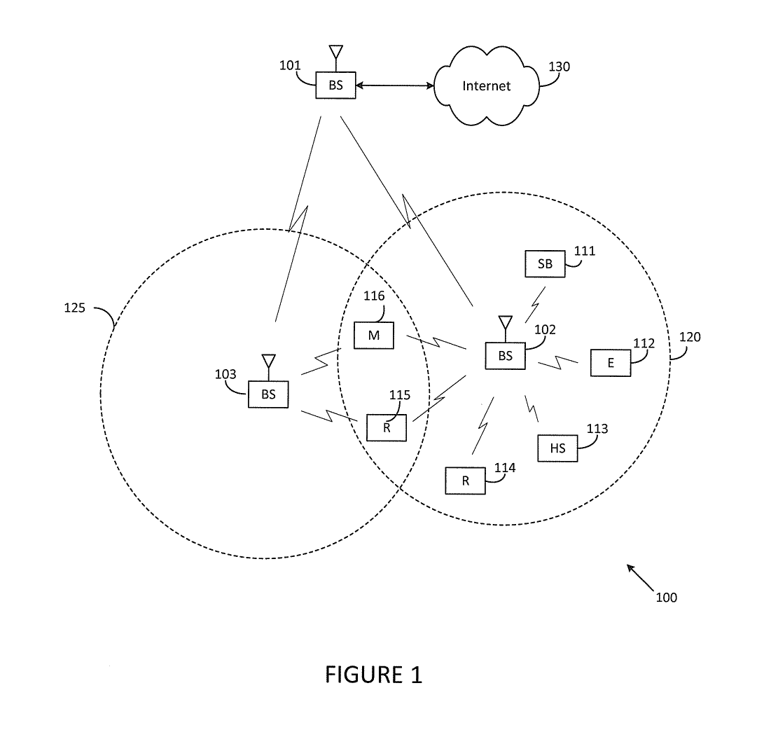

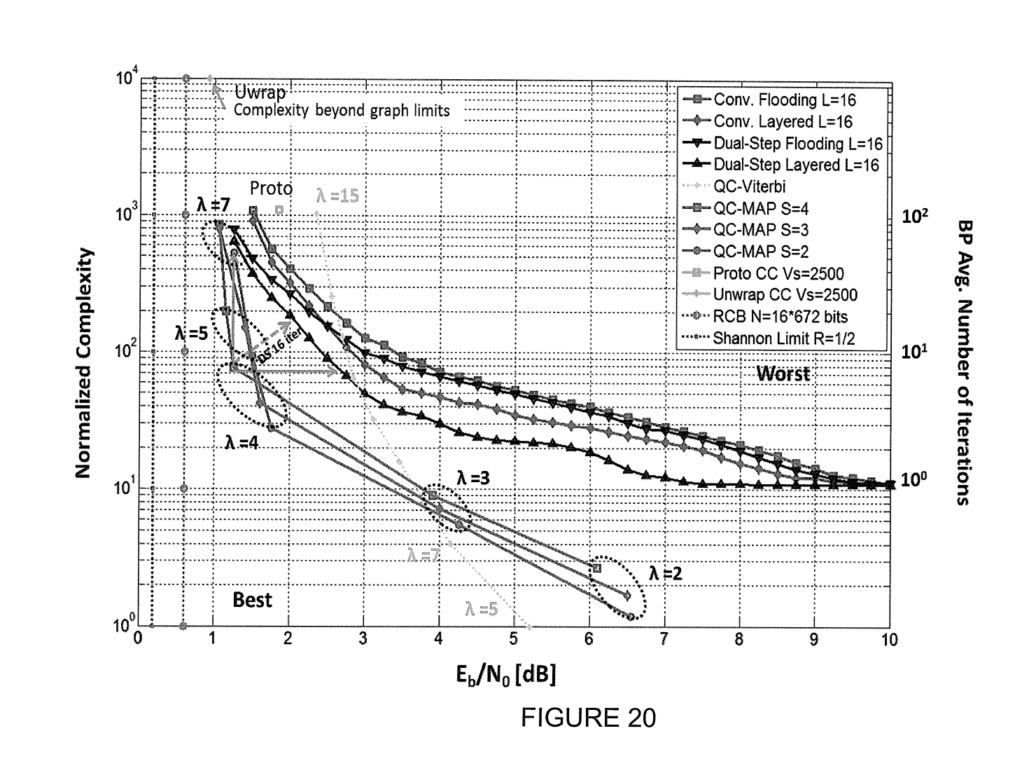

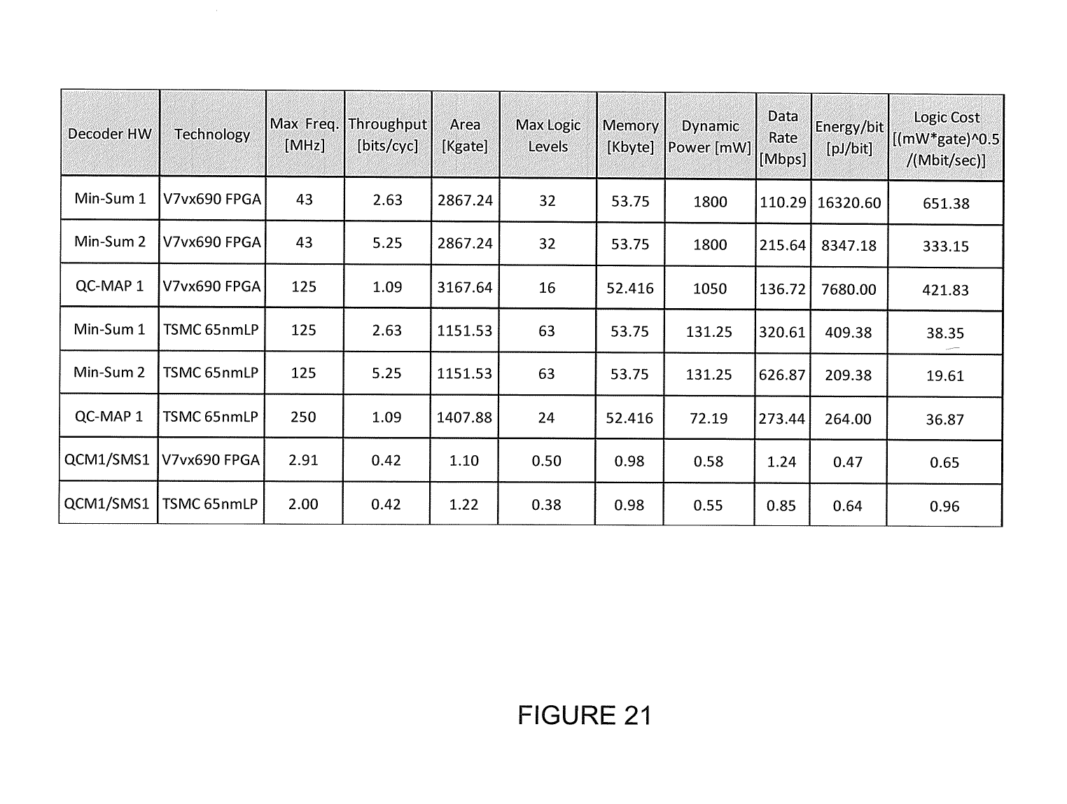

FIGS. 1 through 22, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device or system.

The following documents and standards descriptions are hereby incorporated into the present disclosure as if fully set forth herein: (i) L. Bahl, J. Cocke, F. Jelinek, J. Raviv, “Optimal Decoding of Linear Codes for minimizing symbol error rate”, IEEE Transactions on Information Theory, vol. IT-20(2), pp. 284-287, March 1974 (hereinafter “REF1”); (ii) I. Chatzigeorgiou, M. R. D. Rodrigues, I. J. Wassell, R. Carrasco, “Pseudo-random Puncturing: A Technique to Lower the Error Floor of Turbo Codes,” Information Theory, 2007. ISIT 2007. I FEE International Symposium on, vol., no., pp. 656-660, 24-29 Jun. 2007 (hereinafter “REF2”); (iii) C. Berrou, A. Glavieux and P. Thitimajshima, “Near-Shannon-limit error-correcting and decoding: Turbo codes (1),” in Proc. WEE Int. Conf. Commun., vol. 2, pp. 23-26, Geneva, Switzerland, May 1993 (hereinafter “REF3”); (iv) R. G. Gallager, “Low-density parity-check codes,” Ph.D. dissertation, Massachusetts Institute of Technology, Cambridge, Mass., 1963 (hereinafter “REF4”); (v) D. J. C. MacKay, R. M. Neal, “Near Shannon limit performance of low density parity check codes,” Electronics Letters, vol. 32, pp. 1645-1646, August 1996 (hereinafter “REF5”); (vi) E. Boutillon, J. Castura, F. R. Kschischang, “Decoder-first code design,” Proceedings of the 2nd International Symposium on Turbo Codes and Related Topics, Brest, France, September 2000, pp. 459-462 (hereinafter “REF6”); (vii) T. Zhang, K. K. Parhi, “VLSI implementation-oriented (3,k)-regular low-density parity-check codes,” 2001 IEEE Workshop on Signal Processing Systems, Antwerp, Belgium, September 2001, pp. 25-36 (hereinafter “REF7”); (viii) R. V. Nee, “Breaking the Gigabit-per-second barrier with 802.11AC,” Wireless Communications, IEEE, vol. 18, no. 2, pp. 4-8, April 2011 (hereinafter “REF8”); (ix) IEEE 802.1 1ad standard specification, Part 11: Wireless LAN medium access control (MAC) and physical layer (PHY) Specifications, Amendment 3: “Enhancements for very high throughput in the 60 GHz Band,” [On-line]. Available: http://standards.ieee.org/getieee802/download/802.11ad-2012.pdf [October 2014] (hereinafter “REF9”); (x) T. Baykas, S. Chin-Sean, L. Zhou, J. Wang, M. A. Rahman, H. Harada, S. Kato, “IEEE 802.15.3c: the first IEEE wireless standard for data rates over 1 Gb/s,” Communications Magazine, IEEE, vol. 49, no. 7, pp. 114-121, July 2011 (hereinafter “REF10”); (xi) DVB-S2 Specification, ETSI EN 302 307 V1.2.1, (2009, August), [On-line]. Available: http://www.etsi.org [October 2014] (hereinafter “REF11”); (xii) A. J. Feltström, K. S. Zigangirov, “Time-varying periodic convolutional codes with low-density parity-check matrix,” IEEE Transactions on IT, vol. IT-45, no. 6, pp. 2181-2191, September 1999 (hereinafter “REF12”); (xiii) A. E. Pusane, A. J. Feltström, A. Sridharan, M. Lentimaier, K. S. Zigangirov, and D. J. Costello, Jr., “Implementation Aspects of LDPC convolutional Codes,” IEEE Transactions on Communications, vol. 56, no. 7, pp. 1060-1069, July 2008 (hereinafter “REF13”); (xiv) R. M. Tanner, D. Sridhara, A. Sridharan, T. E. Fuja, D. J. Costello, Jr., “LDPC Block and Convolutional Codes Based on Circulant Matrices,” IEEE Transactions on Information Theory, vol. 50, no. 12, pp. 2966 -2984, December 2004 (hereinafter “REF14”); (xv) D. J. Costello, Jr., L. Dolecek, T. E. Fuja, J. Kliewer, D. G. M. Mitchell, R. Smarandache, (2013, October), “Spatially Coupled Sparse Codes on Graphs—Theory and Practice,” [On-line]. Available: http://arxiv.org/pdf/1310.3724.pdf [October 2014] (hereinafter “REF15”); (xvi) 3GPP LTE Release 8 TSG RAN WG1, [On-Line]. Available: http://www.3gpp.org/RAN1-Radio-layer-1 [October 2014] (hereinafter “REF16”); (xvii) J. Thorpe, “Low-density parity-check (LDPC) codes constructed from protographs,” Jet Propulsion Lab, Pasadena, Calif., INP Progress Report, pp. 42-154, August 2003 (hereinafter “REF17”); (xviii) D. Divsalar, S. Dolinar, and C. Jones, “Protograph LDPC codes over burst erasure channels,” Military Commun., IEEE, October 2006, pp. 1-7 (hereinafter “REF18”); (xix) D. G. M. Mitchell, M. Lentmaier, D. J. Costello, Jr., “New families of LDPC block codes formed by terminating irregular protograph-based LDPC convolutional codes,” in Proc. ISIT 2010, IEEE, Austin, Tex., June 2010, pp. 824-828 (hereinafter “REF19”);.(xx) S. Abu-Surra, E. Pisek, T. Henige, “Gigabit rate achieving low-power LDPC codes: Design and architecture,” WCNC 2011, IEEE, Cancun, Mexico, March 2011. pp. 1994-1999 (hereinafter “REF20”); (xxi) S. Lin, D. J. Costello, Jr., Error Control Coding: Fundamentals and Applications. Englewood Cliffs, N.J.: Prentice-Hall, 2nd ed., 2004 (hereinafter “REF21”); (xxii) E. Pisek, D. Rajan, J. Cleveland, “Gigabit rate low power LDPC decoder,” Information Theory Workshop 2011, Paraty, Brazil, October 2011. pp. 518-522 (hereinafter “REF22”); (xxiii) A. J. Viterbi, “Error bounds for convolutional codes and an asymptotically optimum decoding algorithm,” IEEE Transactions on Information Theory, vol. 13, pp. 260-269, April 1967 (hereinafter “REF23”); (xxiv) G. D. Forney, “The Viterbi algorithm,” Proceedings of the IEEE, vol. 61, pp. 268-278, March 1973 (hereinafter “REF24”); (xxv) A. E. Pusane, R. Smarandache, P. O. Vontobel, D. J. Costello, Jr., “Deriving Good LDPC Convolutional Codes from LDPC Block Codes,” IEEE Transactions on Information Theory, Vol. 57, No. 2, pp. 835 -857, February 2011 (hereinafter “REF25”); (xxvi) J. He, H. Liu, Z. Wang, X. Huang, K. Zhang, “High-Speed Low-Power Viterbi Decoder Design for TCM Decoders,” IEEE Transactions on Very Large Scale Integration (VLSI) Systems, vol. 20, no. 4, pp. 755-759, Apr. 2012 (hereinafter “REF26”); (xxvii) U. G. Nawathe, M. Hassan, K. C. Yen, A. Kumar, A. Ramachandran, D. Greenhill, “Implementation of an 8-Core, 64-Thread, Power-Efficient SPARC Server on a Chip,” IEEE Journal of Solid-State Circuits, vol. 43, no. 1, pp .6-20, January 2008 (hereinafter “REF27”).

FIG. 1 illustrates an example wireless network 100 according to this disclosure. The embodiment of the wireless network 100 shown in FIG. 1 is for illustration only. Other embodiments of the wireless network 100 could be used without departing from the scope of this disclosure.

As shown in FIG. 1, the wireless network 100 includes an eNodeB (eNB) 101, an eNB 102, and an eNB 103. The eNB 101 communicates with the eNB 102 and the eNB 103. The eNB 101 also communicates with at least one Internet Protocol (IP) network 130, such as the Internet, a proprietary IP network, or other data network.

Depending on the network type, other well-known terms may be used instead of “eNodeB” or “eNB,” such as “base station” or “access point.” For the sake of convenience, the terms “eNodeB” and “eNB” are used in this patent document to refer to network infrastructure components that provide wireless access to remote terminals. Also, depending on the network type, other well-known terms may be used instead of “user equipment” or “UE,” such as “mobile station,” “subscriber station,” “remote terminal,” “wireless terminal,” or “user device.” For the sake of convenience, the terms “user equipment” and “UE” are used in this patent document to refer to remote wireless equipment that wirelessly accesses an eNB, whether the UE is a mobile device (such as a mobile telephone or smartphone) or is normally considered a stationary device (such as a desktop computer or vending machine).

The eNB 102 provides wireless broadband access to the network 130 for a first plurality of user equipments (UEs) within a coverage area 120 of the eNB 102. The first plurality of UEs includes a UE 111, which may be located in a small business (SB); a UE 112, which may be located in an enterprise (E); a UE 113, which may be located in a WiFi hotspot (HS); a UE 114, which may be located in a first residence (R); a UE 115, which may be located in a second residence (R); and a UE 116, which may be a mobile device (M) like a cell phone, a wireless laptop, a wireless PDA, or the like. The eNB 103 provides wireless broadband access to the network 130 for a second plurality of UEs within a coverage area 125 of the eNB 103. The second plurality of UEs includes the UE 115 and the UE 116. In some embodiments, one or more of the eNBs 101-103 may communicate with each other and with the UEs 111-116 using 5G, LTE, LTE-A, WiMAX, or other advanced wireless communication techniques.

Dotted lines show the approximate extents of the coverage areas 120 and 125, which are shown as approximately circular for the purposes of illustration and explanation only. It should be clearly understood that the coverage areas associated with eNBs, such as the coverage areas 120 and 125, may have other shapes, including irregular shapes, depending upon the configuration of the eNBs and variations in the radio environment associated with natural and man-made obstructions.

As described in more detail below, one or more of eNBs 101-103 is configured to encode data using a Parallel Concatenated Trellis-based Quasi-Cyclic Low Density Parity Check Recursive Systematic Convolutional (QC-RSC) encoder to encode applying Parallel Concatenated Trellis-based Quasi-Cyclic Low Density Parity Check (PC-LDPC) convolutional code as described in embodiments of the present disclosure. In certain embodiments, one or more of eNBs 101-103 is configured to decode data using a Trellis-based Quasi-Cyclic Low Density Parity Check (TQC-LDPC) Maximum A posteriori Probability (MAP) decoder applying the PC-LDPC convolutional code as described in embodiments of the present disclosure. In certain embodiments, one or more of UEs 111-116 is configured to encode data using a QC-RSC encoder applying PC-LDPC convolutional code as described in embodiments of the present disclosure. In certain embodiments, one or more of UEs 111-116 is configured to decode data using a TQC-LDPC MAP decoder applying the PC-LDPC convolutional code as described in embodiments of the present disclosure.

Although FIG. 1 illustrates one example of a wireless network 100, various changes may be made to FIG. 1. For example, the wireless network 100 could include any number of eNBs and any number of UEs in any suitable arrangement. Also, the eNB 101 could communicate directly with any number of UEs and provide those UEs with wireless broadband access to the network 130. Similarly, each eNB 102-103 could communicate directly with the network 130 and provide UEs with direct wireless broadband access to the network 130. Further, the eNB 101, 102, and/or 103 could provide access to other or additional external networks, such as external telephone networks or other types of data networks.

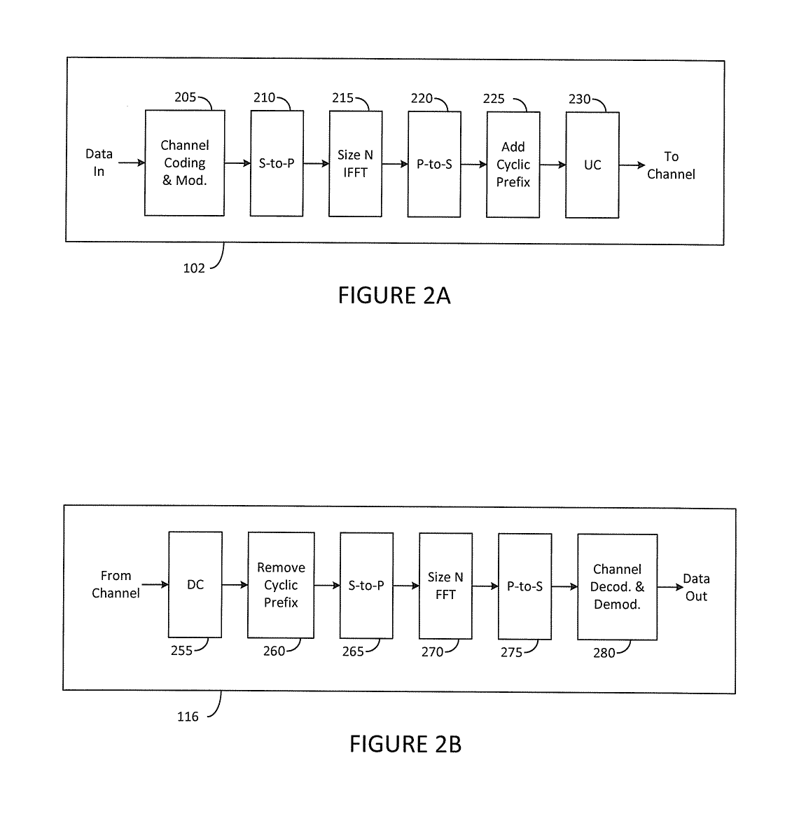

FIGS. 2A and 2B illustrate example wireless transmit and receive paths according to this disclosure. In the following description, a transmit path 200 may be described as being implemented in an eNB (such as eNB 102), while a receive path 250 may be described as being implemented in a UE (such as UE 116). However, it will be understood that the receive path 250 could be implemented in an eNB and that the transmit path 200 could be implemented in a UE. In certain embodiments, the transmit path 200 is configured to encode data using a QC-RSC encoder applying PC-LDPC convolutional code as described in embodiments of the present disclosure. In certain embodiments, the receive path 250 is configured to decode data a TQC-LDPC MAP decoder applying the PC-LDPC convolutional code as described in embodiments of the present disclosure.

The transmit path 200 includes a channel coding and modulation block 205, a serial-to-parallel (S-to-P) block 210, a size N Inverse Fast Fourier Transform (IFFT) block 215, a parallel-to-serial (P-to-S) block 220, an add cyclic prefix block 225, and an up-converter (UC) 230. The receive path 250 includes a down-converter (DC) 255, a remove cyclic prefix block 260, a serial-to-parallel (S-to-P) block 265, a size N Fast Fourier Transform (FFT) block 270, a parallel-to-serial (P-to-S) block 275, and a channel decoding and demodulation block 280.

In the transmit path 200, the channel coding and modulation block 205 receives a set of information bits, applies coding (such as a low-density parity check (LDPC) coding), and modulates the input bits (such as with Quadrature Phase Shift Keying (QPSK) or Quadrature Amplitude Modulation (QAM)) to generate a sequence of frequency-domain modulation symbols. The serial-to-parallel block 210 converts (such as de-multiplexes) the serial modulated symbols to parallel data in order to generate N parallel symbol streams, where N is the IFFT/FFT size used in the eNB 102 and the UE 116. The size N IFFT block 215 performs an IFFT operation on the N parallel symbol streams to generate time-domain output signals. The parallel-to-serial block 220 converts (such as multiplexes) the parallel time-domain output symbols from the size N IFFT block 215 in order to generate a serial time-domain signal. The add cyclic prefix block 225 inserts a cyclic prefix to the time-domain signal. The up-converter 230 modulates (such as up-converts) the output of the add cyclic prefix block 225 to an RF frequency for transmission via a wireless channel. The signal may also be filtered at baseband before conversion to the RF frequency.

A transmitted RF signal from the eNB 102 arrives at the UE 116 after passing through the wireless channel, and reverse operations to those at the eNB 102 are performed at the UE 116. The down-converter 255 down-converts the received signal to a baseband frequency, and the remove cyclic prefix block 260 removes the cyclic prefix to generate a serial time-domain baseband signal. The serial-to-parallel block 265 converts the time-domain baseband signal to parallel time domain signals. The size N FFT block 270 performs an FFT algorithm to generate N parallel frequency-domain signals. The parallel-to-serial block 275 converts the parallel frequency-domain signals to a sequence of modulated data symbols. The channel decoding and demodulation block 280 demodulates and decodes the modulated symbols to recover the original input data stream.

Each of the eNBs 101-103 may implement a transmit path 200 that is analogous to transmitting in the downlink to UEs 111-116 and may implement a receive path 250 that is analogous to receiving in the uplink from UEs 111-116. Similarly, each of UEs 111-116 may implement a transmit path 200 for transmitting in the uplink to eNBs 101-103 and may implement a receive path 250 for receiving in the downlink from eNBs 101-103.

Each of the components in FIGS. 2A and 2B can be implemented using only hardware or using a combination of hardware and software/firmware. As a particular example, at least some of the components in FIGS. 2A and 2B may be implemented in software, while other components may be implemented by configurable hardware or a mixture of software and configurable hardware. For instance, the FFT block 270 and the IFFT block 215 may be implemented as configurable software algorithms, where the value of size N may be modified according to the implementation.

Furthermore, although described as using FFT and IFFT, this is by way of illustration only and should not be construed to limit the scope of this disclosure. Other types of transforms, such as Discrete Fourier Transform (DFT) and Inverse Discrete Fourier Transform (IDFT) functions, could be used. It will be appreciated that the value of the variable N may be any integer number (such as 1, 2, 3, 4, or the like) for DFT and IDFT functions, while the value of the variable N may be any integer number that is a power of two (such as 1, 2, 4, 8, 16, or the like) for FFT and IFFT functions.

Although FIGS. 2A and 2B illustrate examples of wireless transmit and receive paths, various changes may be made to FIGS. 2A and 2B. For example, various components in FIGS. 2A and 2B could be combined, further subdivided, or omitted and additional components could be added according to particular needs. Also, FIGS. 2A and 2B are meant to illustrate examples of the types of transmit and receive paths that could be used in a wireless network. Any other suitable architectures could be used to support wireless communications in a wireless network.

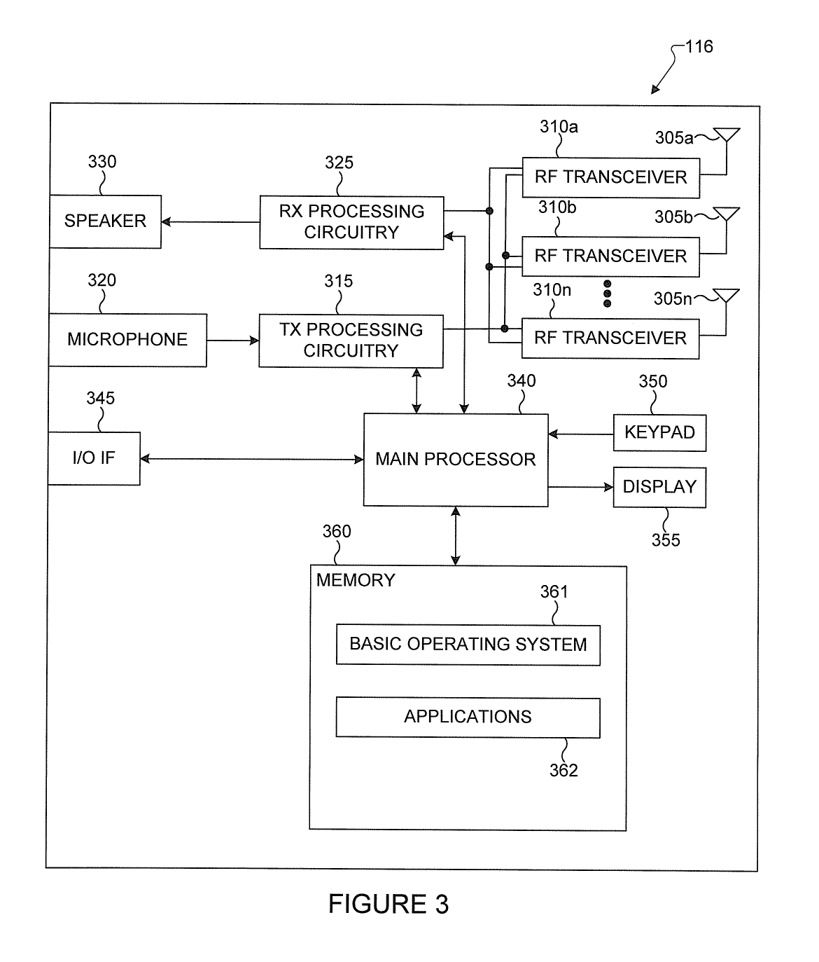

FIG. 3 illustrates an example UE 116 according to this disclosure. The embodiment of the UE 116 illustrated in FIG. 3 is for illustration only, and the UEs 111-115 of FIG. 1A could have the same or similar configuration. However, UEs come in a wide variety of configurations, and FIG. 3 does not limit the scope of this disclosure to any particular implementation of a UE.

The UE 116 includes multiple antennas 305a-305n, radio frequency (RF) transceivers 310a-310n, transmit (TX) processing circuitry 315, a microphone 320, and receive (RX) processing circuitry 325. The TX processing circuitry 315 and RX processing circuitry 325 are respectively coupled to each of the RF transceivers 310a-310n, for example, coupled to RF transceiver 310a, RF transceiver 210b through to a N^{th} RF transceiver 310n, which are coupled respectively to antenna 305a, antenna 305b and an N^{th} antenna 305n. In certain embodiments, the UE 116 includes a single antenna 305a and a single RF transceiver 310a. The UE 116 also includes a speaker 330, a main processor 340, an input/output (I/O) interface (IF) 345, a keypad 350, a display 355, and a memory 360. The memory 360 includes a basic operating system (OS) program 361 and one or more applications 362.

The RF transceivers 310a-310n receive, from respective antennas 305a-305n, an incoming RF signal transmitted by an eNB or AP of the network 100. In certain embodiments, each of the RF transceivers 310a-310n and respective antennas 305a-305n is configured for a particular frequency band or technological type. For example, a first RF transceiver 310a and antenna 305a can be configured to communicate via a near-field communication, such as BLUETOOTH®, while a second RF transceiver 310b and antenna 305b can be configured to communicate via a IEEE 802.11 communication, such as Wi-Fi, and another RF transceiver 310n and antenna 305n can be configured to communicate via cellular communication, such as 3G, 4G, 5G, LTE, LTE-A, or WiMAX. In certain embodiments, one or more of the RF transceivers 310a-310n and respective antennas 305a-305n is configured for a particular frequency band or same technological type. The RF transceivers 310a-310n down—converts the incoming RF signal to generate an intermediate frequency (IF) or baseband signal. The IF or baseband signal is sent to the RX processing circuitry 325, which generates a processed baseband signal by filtering, decoding, and/or digitizing the baseband or IF signal. The RX processing circuitry 325 transmits the processed baseband signal to the speaker 330 (such as for voice data) or to the main processor 340 for further processing (such as for web browsing data).

The TX processing circuitry 315 receives analog or digital voice data from the microphone 320 or other outgoing baseband data (such as web data, e-mail, or interactive video game data) from the main processor 340. The TX processing circuitry 315 encodes, multiplexes, and/or digitizes the outgoing baseband data to generate a processed baseband or IF signal. The RF transceivers 310a-310n receive the outgoing processed baseband or IF signal from the TX processing circuitry 315 and up-converts the baseband or IF signal to an RF signal that is transmitted via one or more of the antennas 305a-305n.

The main processor 340 can include one or more processors or other processing devices and execute the basic OS program 361 stored in the memory 360 in order to control the overall operation of the UE 116. For example, the main processor 340 could control the reception of forward channel signals and the transmission of reverse channel signals by the RF transceivers 310a-310n, the RX processing circuitry 325, and the TX processing circuitry 315 in accordance with well-known principles. In some embodiments, the main processor 340 includes at least one microprocessor or microcontroller. The main processor 340 includes processing circuitry configured to encode or decode data information, such as including a QC-RSC encoder processing circuitry configured to apply PC-LDPC convolutional code, a TQC-LDPC MAP decoder processing circuitry configured to apply the PC-LDPC convolutional code; a QC-RSC encoder; a TQC-LDPC MAP decoder; or a combination thereof.

The main processor 340 is also capable of executing other processes and programs resident in the memory 360, such as operations for applying PC-LDPC convolutional code for encoding in a QC-RSC encoder or decoding in TQC-LDPC MAP decoder as described in embodiments of the present disclosure. The main processor 340 can move data into or out of the memory 360 as required by an executing process. In some embodiments, the main processor 340 is configured to execute the applications 362 based on the OS program 361 or in response to signals received from eNBs or an operator. The main processor 340 is also coupled to the I/O interface 345, which provides the UE 116 with the ability to connect to other devices such as laptop computers and handheld computers. The I/O interface 345 is the communication path between these accessories and the main controller 340.

The main processor 340 is also coupled to the keypad 350 and the display unit 355. The user of the UE 116 can use the keypad 350 to enter data into the UE 116. The display 355 can be a liquid crystal display or other display capable of rendering text or at least limited graphics, such as from web sites, or a combination thereof.

The memory 360 is coupled to the main processor 340. Part of the memory 360 could include a random access memory (RAM), and another part of the memory 360 could include a Flash memory or other read-only memory (ROM).

Although FIG. 3 illustrates one example of UE 116, various changes may be made to FIG. 3. For example, various components in FIG. 3 could be combined, further subdivided, or omitted and additional components could be added according to particular needs. As a particular example, the main processor 340 could be divided into multiple processors, such as one or more central processing units (CPUs) and one or more graphics processing units (GPUs). Also, while FIG. 3 illustrates the UE 116 configured as a mobile telephone or smartphone, UEs could be configured to operate as other types of mobile or stationary devices.

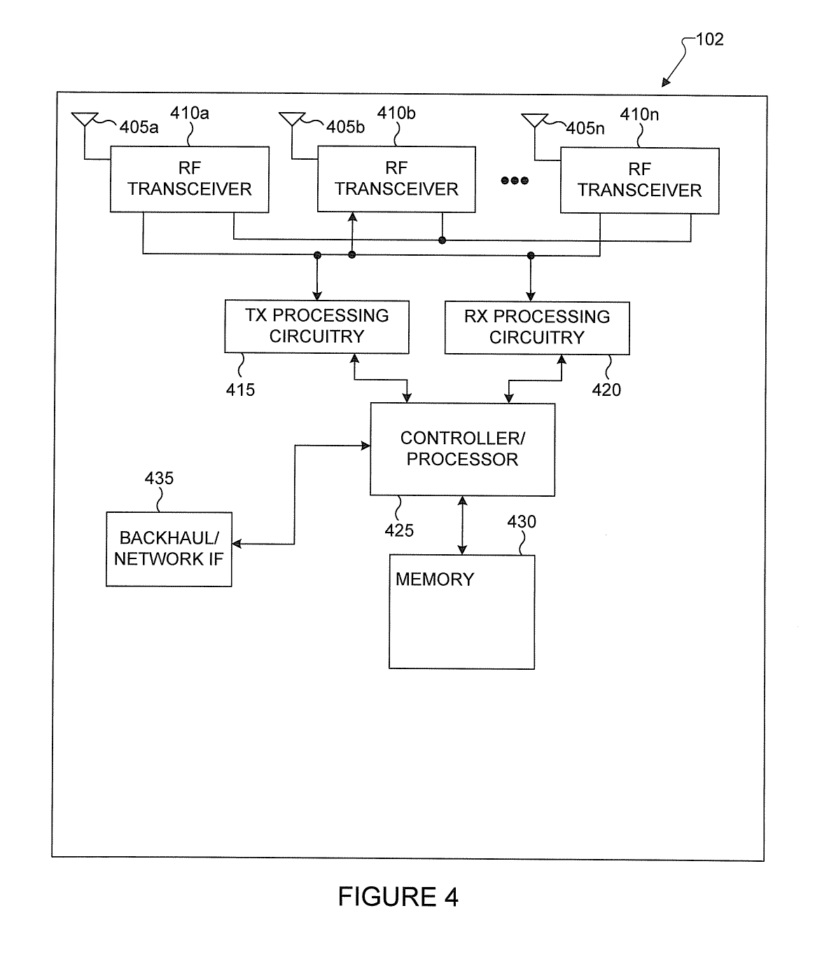

FIG. 4 illustrates an example eNB 102 according to this disclosure. The embodiment of the eNB 102 shown in FIG. 4 is for illustration only, and other eNBs of FIG. 1 could have the same or similar configuration. However, eNBs come in a wide variety of configurations, and FIG. 4 does not limit the scope of this disclosure to any particular implementation of an eNB.

The eNB 102 includes multiple antennas 405a-405n, multiple RF transceivers 410a-410n, transmit (TX) processing circuitry 415, and receive (RX) processing circuitry 420. The eNB 102 also includes a controller/processor 425, a memory 430, and a backhaul or network interface 435.

The RF transceivers 410a-410n receive, from the antennas 405a-405n, incoming RF signals, such as signals transmitted by UEs or other eNBs. The RF transceivers 410a-410n down-convert the incoming RF signals to generate If or baseband signals. The IF or baseband signals are sent to the RX processing circuitry 420, which generates processed baseband signals by filtering, decoding, and/or digitizing the baseband or If signals. The RX processing circuitry 420 transmits the processed baseband signals to the controller/processor 425 for further processing.

The TX processing circuitry 415 receives analog or digital data (such as voice data, web data, e-mail, or interactive video game data) from the controller/processor 425. The TX processing circuitry 415 encodes, multiplexes, and/or digitizes the outgoing baseband data to generate processed baseband or IF signals. The RF transceivers 410a-410n receive the outgoing processed baseband or IF signals from the TX processing circuitry 415 and up-converts the baseband or IF signals to RF signals that are transmitted via the antennas 405a-405n.

The controller/processor 425 can include one or more processors or other processing devices that control the overall operation of the eNB 102. For example, the controller/processor 425 could control the reception of forward channel signals and the transmission of reverse channel signals by the RF transceivers 410a-410n, the RX processing circuitry 420, and the TX processing circuitry 415 in accordance with well-known principles. The controller/processor 425 could support additional functions as well, such as applying PC-LDPC convolutional code for encoding in a QC-RSC encoder or decoding in TQC-LDPC MAP decoder as described in embodiments of the present disclosure. Any of a wide variety of other functions could be supported in the eNB 102 by the controller/processor 425. In some embodiments, the controller/processor 425 includes at least one microprocessor or microcontroller. The controller/processor 425 includes processing circuitry configured to encode or decode data information, such as including a QC-RSC encoder that applies PC-LDPC convolutional code for encoding data, a TQC-LDPC MAP decoder the applies the PC-LDPC convolutional code for decoding data; a QC-RSC encoder; a TQC-LDPC MAP decoder; or a combination thereof.

The controller/processor 425 is also capable of executing programs and other processes resident in the memory 430, such as a basic OS. The controller/processor 425 can move data into or out of the memory 430 as required by an executing process.

The controller/processor 425 is also coupled to the backhaul or network interface 435. The backhaul or network interface 435 allows the eNB 102 to communicate with other devices or systems over a backhaul connection or over a network. The interface 435 could support communications over any suitable wired or wireless connection(s). For example, when the eNB 102 is implemented as part of a cellular communication system (such as one supporting 5G, LTE, or LTE-A), the interface 435 could allow the eNB 102 to communicate with other eNBs over a wired or wireless backhaul connection. When the eNB 102 is implemented as an access point, the interface 435 could allow the eNB 102 to communicate over a wired or wireless local area network or over a wired or wireless connection to a larger network (such as the Internet). The interface 435 includes any suitable structure supporting communications over a wired or wireless connection, such as an Ethernet or RF transceiver.

The memory 430 is coupled to the controller/processor 425. Part of the memory 330 could include a RAM, and another part of the memory 430 could include a Flash memory or other ROM.

As described in more detail below, the transmit and receive paths of the eNB 102 (implemented using the RF transceivers 410a-410n, TX processing circuitry 415, and/or RX processing circuitry 420) support communication with aggregation of FDD cells and TDD cells.

Although FIG. 4 illustrates one example of an eNB 102, various changes may be made to FIG. 4. For example, the eNB 102 could include any number of each component shown in FIG. 4. As a particular example, an access point could include a number of interfaces 435, and the controller/processor 425 could support routing functions to route data between different network addresses. As another particular example, while shown as including a single instance of TX processing circuitry 415 and a single instance of RX processing circuitry 420, the eNB 102 could include multiple instances of each (such as one per RF transceiver).

LDPC codes have received a great deal of attention in recent years. This is due to their ability to achieve performance close to the Shannon limit, the ability to design codes that facilitate high parallelization in hardware, and their support of high data rates. The most commonly deployed form of the LDPC codes are the block LDPC codes. However, in highly dynamic wireless communication systems, where the channel conditions and the data allocation per user are continuously changing, block LDPC codes offer rather limited flexibility.

Using block LDPC codes requires allocating data in multiples of the code's block-length to avoid unnecessary padding, which reduces the link efficiency. Amongst the wireless standards that have adopted LDPC as a part of the specification, the following three approaches can be observed to handle the granularity limitation of block LDPC codes: 1) Use codes with one very short block-length, such as, IEEE 802.11ad, the smaller the block length the finer the granularity of the code, however, block LDPC codes with short block lengths are lacking in performance, which also reduces the link efficiency; 2) Use block LDPC codes with multiple block lengths, such as, IEEE 802.11n, and this approach mitigates the performance degradation at the expense of implementing a more complex decoder due to the requirement to support multiple codes; and 3) Use turbo codes, such as, 3GPP. The convolutional structure of turbo codes can provide a scalable code-length with high granularity without increasing the decoder's complexity. However, turbo codes do not provide enough parallel processing capability, which in turn limits their capability to achieve multiple Giga bits per second throughput.

Parallel Concatenated Trellis-based Quasi-Cyclic Low Density Parity Check (PC-LDPC) convolutional codes are new capacity-approaching codes, which are a special case of Trellis-based Quasi-Cyclic LDPC (TQC-LDPC) convolutional codes. A PC-LDPC convolutional code can be derived from any QC-LDPC block code by introducing trellis-based convolutional dependency to the code. PC-LDPC codes combine the advantages of both convolutional LDPC codes and LDPC block codes. PC-LDPC codes form a special class of LDPC codes that reduces LDPC block granularity from a block size (y) granularity to a fine input granularity on the order of a lifting-factor (Z) size granularity of the underlying block code. The PC-LDPC convolutional code maintains a low bit error ratio (BER) and enables low complexity (X) encoder and decoder architecture. Hence, PC-LDPC codes have parity check matrices with convolutional structure. This structure allows for scalable code-length with fine granularity compared to the other block LDPC codes. In addition, PC-LDPC codes inherit the high parallel processing capabilities of LDPC codes, and are therefore capable of supporting multiple GBs throughput.

The capacity-approaching PC-LDPC convolutional codes are encoded through Parallel Concatenated Trellis-based Quasi-Cyclic LDPC Recursive Systematic Convolutional encoder namely, a QC-RSC encoder.

The PC-LDPC convolutional codes with the QC-MAP decoder have two times lower complexity for a given Bit-Error-Rate (BER), Signal-to-Noise Ratio (SNR), and data rate, than conventional QC-LDPC block codes and conventional LDPC convolutional codes. The PC-LDPC convolutional code with the QC-MAP decoder outperforms the conventional QC-LDPC block codes by more than 0.5 dB for a given Bit-Error-Rate (BER), complexity, and data rate and approaches Shannon capacity limit with a gap smaller than 1.25 dB. This low decoding complexity and the fine granularity makes it feasible for the proposed capacity-approaching PC-LDPC convolutional code and the associated trellis-based QC-MAP decoder to be efficiently implemented in ultra-high data rate next generation mobile systems.

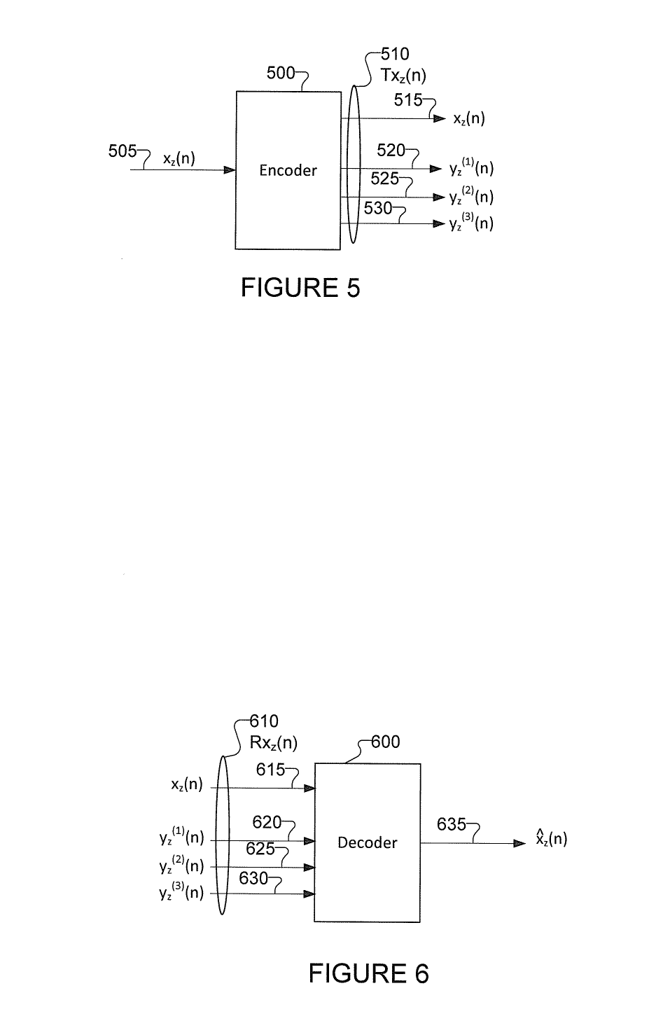

FIG. 5 illustrates a Parallel Concatenated Trellis-based Quasi-Cyclic Low Density Parity Check Recursive Systematic Convolutional (QC-RSC) encoder 500 according to this disclosure. The embodiment of the QC-RSC encoder 500 shown in FIG. 5 is for illustration only. Other embodiments could be used without departing from the scope of the present disclosure.

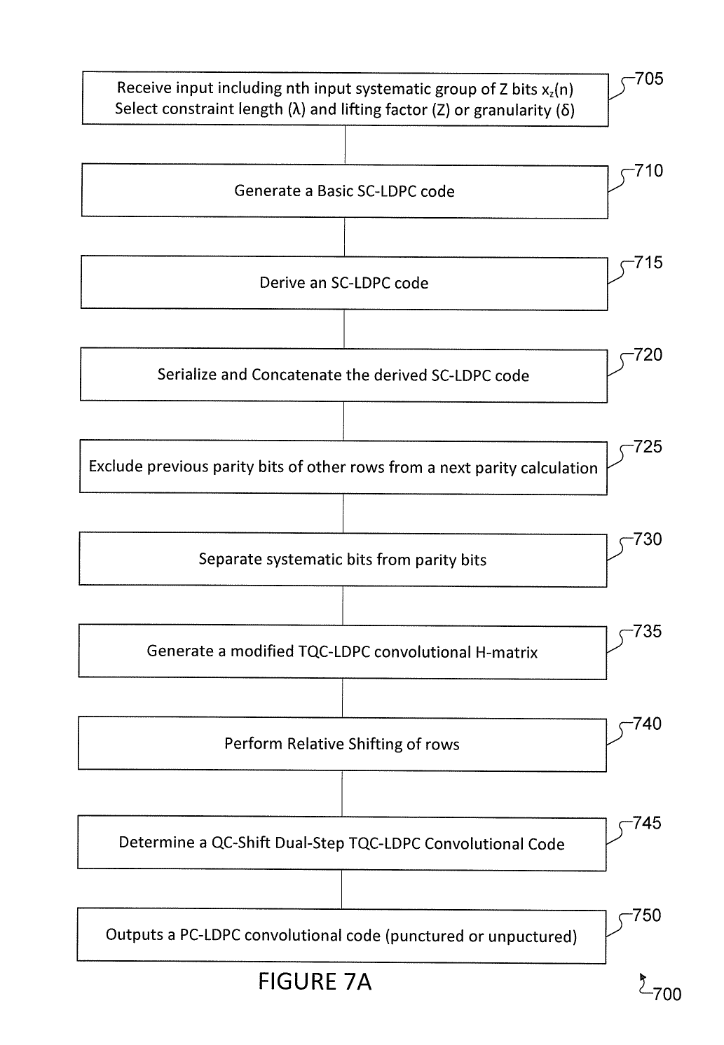

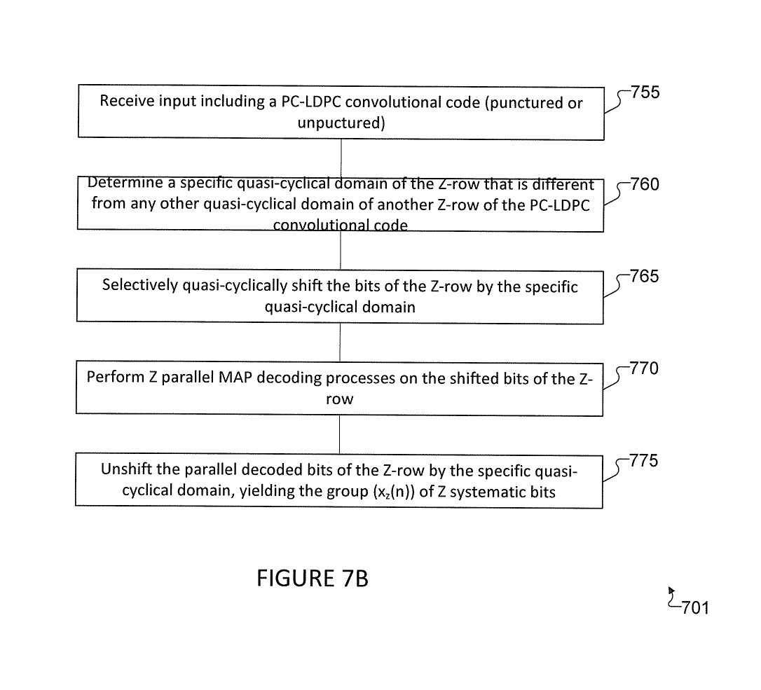

The QC-RSC encoder 500 can be included in the UE 116 or in the eNB 102. The QC-RSC encoder 500 receives information to be encoded as input 505. More particularly, the input 505 includes systematic data in the form of a Z-group of systematic bits x_{z}(n). The QC-RSC encoder 500 encodes the input 505 by implementing a PC-LDPC encoding process 700 (described in further detail with reference to FIG. 7A). The QC-RSC encoder 500 outputs an encoded version of the received information as output 510. The encoded information output 510 includes a code block in the form of an H-matrix, wherein the H-matrix includes a systematic submatrix (H_{sys}) of the input systematic data and a parity check submatrix (Hₚₐᵣ) of parity check bits. The systematic submatrix (H_{sys}) includes the information inputted to the encoder 500. The parity check submatrix (Hₚₐᵣ) includes one or more parity bits per systematic bit. In the example shown, the output 510 includes the systematic data x_{z}(n) 515, a first Z-group of parity bits y_{z}⁽¹⁾(n) 520, a second Z-group of parity bits y_{z}⁽²⁾(n) 525, and a third Z-group of parity bits y_{z}⁽³⁾(n) 530.

The QC-RSC encoder 500 is configured based on an underlying LDPC block code parity check matrix H having a lifting factor Z and JZ rows (referred to as J sets of Z-rows) and BZ systematic columns (referred to as B sets of systematic Z-columns). That is, the underlying LDPC block code parity check matrix H includes a systematic part and a parity part, namely, a systematic submatrix (H_{sys}) and a parity check submatrix (Hₚₐᵣ) The underlying LDPC block code parity check matrix H is defined according to Equation 1. The parity check submatrix (Hₚₐᵣ) includes the J sets of Z-rows and a number (for example, J) of sets of parity Z-columns. The systematic submatrix (H_{sys}) includes the J sets of Z-rows and the B sets of systematic Z-columns. The systematic submatrix (H_{sys}) is defined according to Equation 2. The systematic submatrix (H_{sys}) includes JB Z-groups, each referred to as H _{z}_{_{sys}}(j,l )). As shown in Equation 3, the systematic part of the j-th Z-row and l-th Z-column of the underlying LDPC block code H is defined as H_{z}_{_{sys}}(j,l) for j=0, . . . , J−1, and l=0 , . . . , B−1. The input 505 is an input sequence that includes one or more cyclically shifted Z-group input bits, wherein x_{z}(n) is defined as the n-th group of Z (namely Z-group) bits of the input sequence, and wherein n is an index of the input sequence from n=0 , . . . , JB−1. More particularly, the n-th cyclically shifted Z-group input bits corresponding to the j-th Z-row of H_{z}_{_{sys}} is referred to as x_{z}^{(j)}(n), as defined in Equations 4, where (n mod B) is n modulo B.

$$\begin{matrix} H = {H}_{sys} \vert {H}_{par} & ( 1 ) \\ {H}_{sys} = [ \begin{matrix}{H}_{{Z}_{sys}} ( 0 , 0 ) & {H}_{{Z}_{sys}} ( j , l ) & … & {H}_{{Z}_{sys}} ( 0 , B - 1 ) \\ ⋮ & ⋮ & ⋱ & ⋮ \\ {H}_{{Z}_{sys}} ( J - 1 , 0 ) & {H}_{{Z}_{sys}} ( j , l ) & … & {H}_{{Z}_{sys}} ( J - 1 , B - 1 )\end{matrix} ] & ( 2 ) \\ {H}_{{Z}_{sys}} ( j , l ) = [ \begin{matrix}{x}_{Z}^{( 0 )} ( 0 ) & {x}_{Z}^{( j )} ( n ) & … & {x}_{Z}^{( 0 )} ( Z - 1 ) \\ ⋮ & ⋮ & ⋱ & ⋮ \\ {x}_{Z}^{( Z - 1 )} ( 0 ) & {x}_{Z}^{( j )} ( n ) & … & {x}_{Z}^{( Z - 1 )} ( Z - 1 )\end{matrix} ] & ( 3 ) \\ {x}_{z}^{( j )} ( n ) ≡ {x}_{z} ( n ) {H}_{{Z}_{sys}}^{T} ( n mod B , j ) & ( 4 )\end{matrix}$$

FIG. 6 illustrates a Trellis-based Quasi-Cyclic Low Density Parity Check (TQC-LDPC) Maximum A posteriori Probability (MAP) decoder 600 according to this disclosure. The embodiment of the TQC-LDPC MAP decoder 600 shown in FIG. 6 is for illustration only. Other embodiments could be used without departing from the scope of the present disclosure.

The TQC-LDPC MAP decoder 600 can be included in the UE 116 or in the eNB 102. The TQC-LDPC MAP decoder 600 receives information Rx_{z}(n) to be decoded and a set of parity log-likelihood ratios (LLR) as input 610. In the input 610, the Rx_{z}(n) is the n-th Z-group received systematic log-likelihood ratio (LLR) set in a non-interleaved mode. Also, the set of parity LLRs are referred to as Ry_{z}^{(j)}(n),j∈{0 , . . . J−1=2} where each Ry_{z}^{(j)}(n) is already interleaved by the corresponding quasi-cyclic shifts related to H_{z}_{_{sys}} Z-row j. More particularly, the input 610 includes encoded information, namely, a code block in the form of an H-matrix, wherein the H-matrix includes a systematic submatrix (H_{sys}) of the input systematic data and a parity check submatrix (Hₚₐᵣ) of parity check bits. The systematic submatrix (H_{sys}) includes the information inputted to the encoder 500. The parity check submatrix (Hₚₐᵣ) includes one or more parity bits per systematic bit. In the example shown, the input 610 includes the systematic data 615 in the form of a Z-group of systematic bits X (n), a first Z-group of parity bits y_{z}⁽¹⁾(n) 620, a second Z-group of parity bits y_{z}⁽²⁾(n) 625, and a third Z-group of parity bits y_{z}⁽³⁾(n) 630. The TQC-LDPC MAP decoder 600 decodes the input 610 by implementing a PC-LDPC decoding process (described in further detail below). The TQC-LDPC MAP decoder 600 outputs an decoded version of the received information as output 635.

For simplicity, this disclosure will be described in the context of an example scenario in which the eNB 102 includes the QC-RSC encoder and transmits the encoded information output Tx_{z}(n) 510 to the UE 116, and correspondingly, the UE 116 includes the decoder 600 receives encoded information Rx_{z}(n) 610. In the case of a perfect channel between the transmitter of the eNB 102 and receiver of the UE 116, the output 510 from the encoder 500 is identical to the input 610 to the decoder 600. In the case of perfect operation of the encoder 500 and decoder 600, the systematic information x_{z}(n) 505 is identical to the information 515, 615, and 635; and the first parity information y_{z}⁽¹⁾(n) 520 is the same as the information 620; the second parity information y_{z}⁽²⁾(n) 525 is the same as the information 625, and the third parity information y_{z}⁽³⁾(n) 530 is the same as the information 630.

FIG. 7A illustrates a PC-LDPC encoding process 700 according to this disclosure. While the flow chart depicts a series of sequential steps, unless explicitly stated, no inference should be drawn from that sequence regarding specific order of performance, performance of steps or portions thereof serially rather than concurrently or in an overlapping manner, or performance of the steps depicted exclusively without the occurrence of intervening or intermediate steps. The process depicted in the example depicted is implemented by encoder circuitry or processing circuitry in a transmitter such as, for example, in a base station.

In block 705, the QC-RSC encoder 500 receives the input 505 of information to be encoded. Also in block 705, the QC-RSC encoder 500 selects a lifting factor (Z) and a constraint length (X) the input 505. The lifting factor (Z) represents the input granularity (δ), as the QC-RSC encoder 500 is configured to encode a matrix of systematic data having a size of Z×Z permutation matrix.

In block 710, the QC-RSC encoder 500 generates a Spatially-Coupled (SC) Low Density Parity Check (LDPC) base code based on the input 505. The SC-LDPC base code is discussed in further detail with reference to FIGS. 10 and 11. The SC-LDPC base code is characterized by a row weight (Wr), a column weight (Wc), and a first level lifting factor (Z).

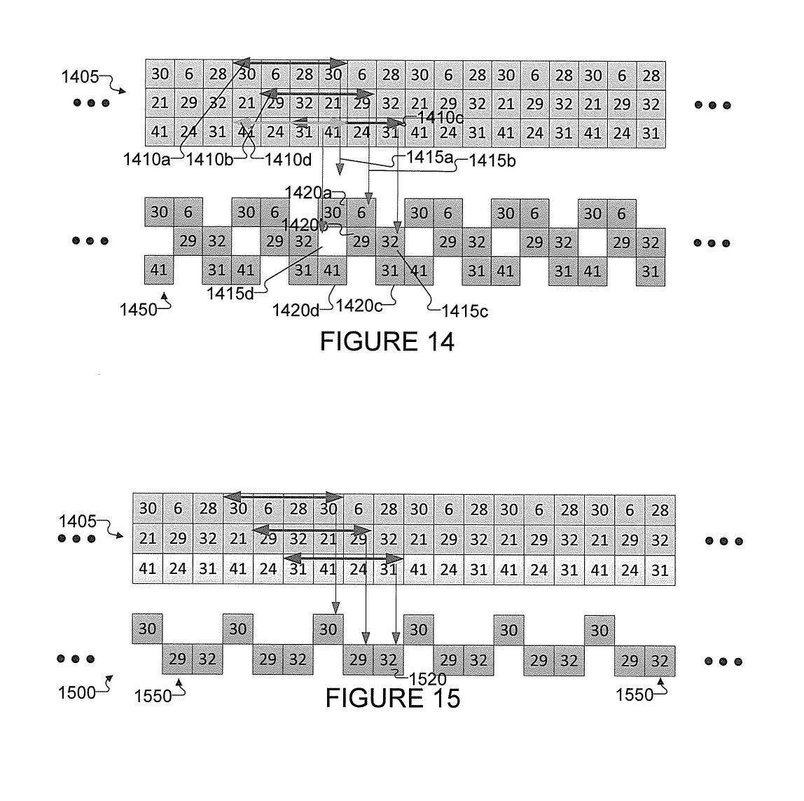

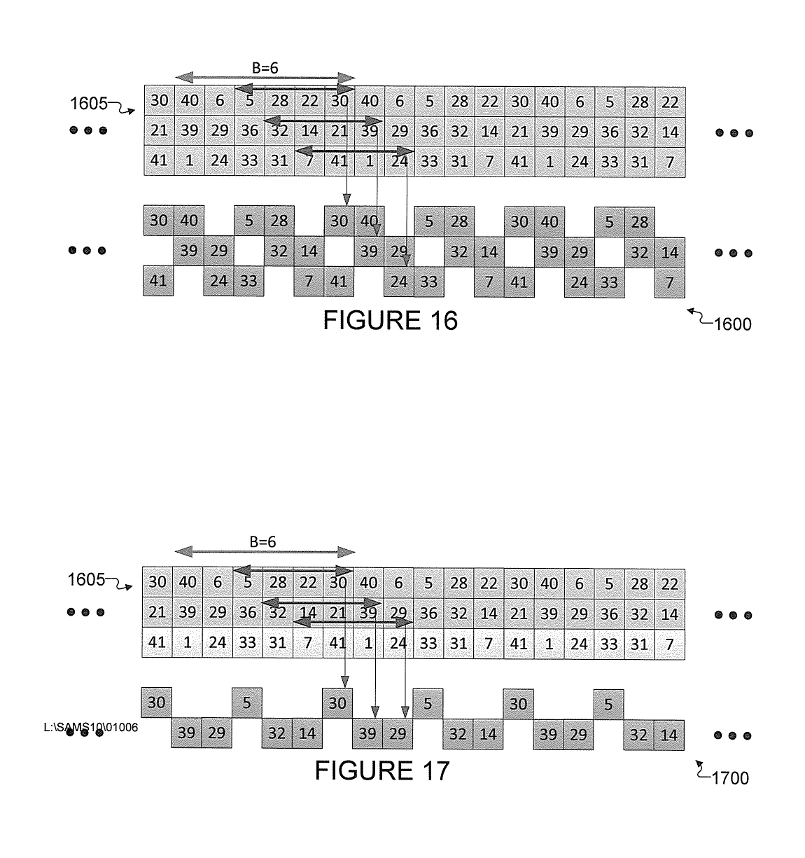

As part of deriving the SC-LDPC base code, the QC-RSC encoder 500 can reduce the bit error rate (BER) and periodicity of the convolutional code by increasing the size (B) of the underlying LDPC systematic H-matrix (H_{z}_{_{sys}}) in Z-group bits. The size (B) of the H_{z}_{_{sys}} matrix is equivalent to the row weight (Wr) of the SC-LDPC base code. Such a reduction is shown by comparing the size B=3 modified TQC-LDPC convolutional H-Matrix of FIGS. 14-15 to the size B=6 modified TQC-LDPC convolutional H-Matrix of FIGS. 16-17.

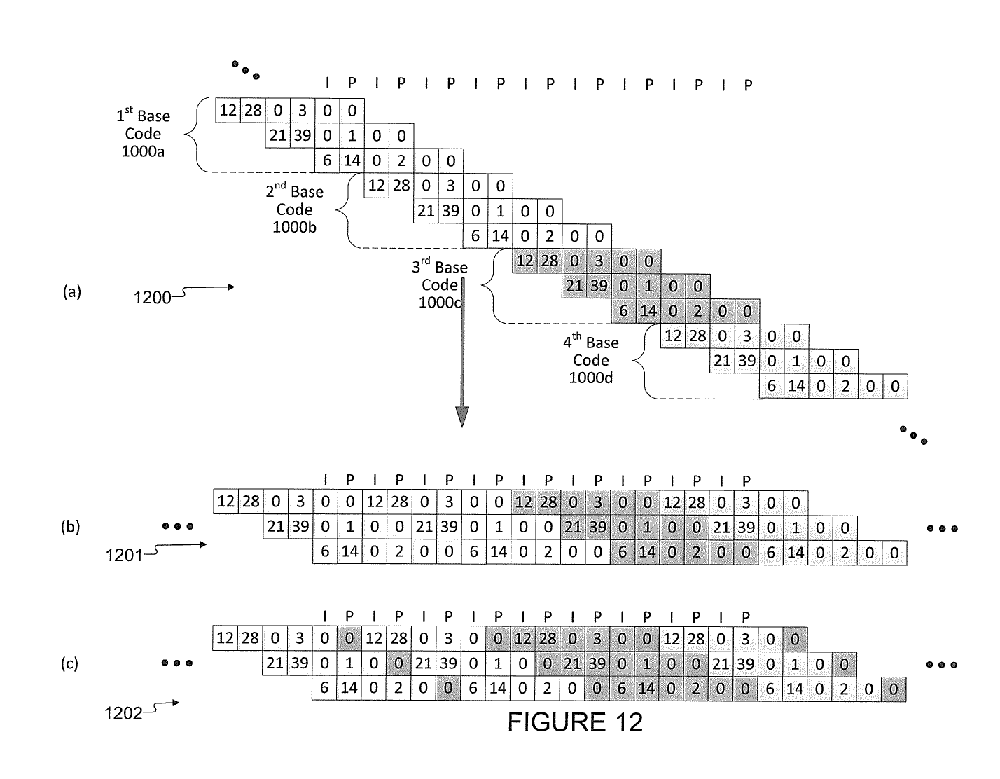

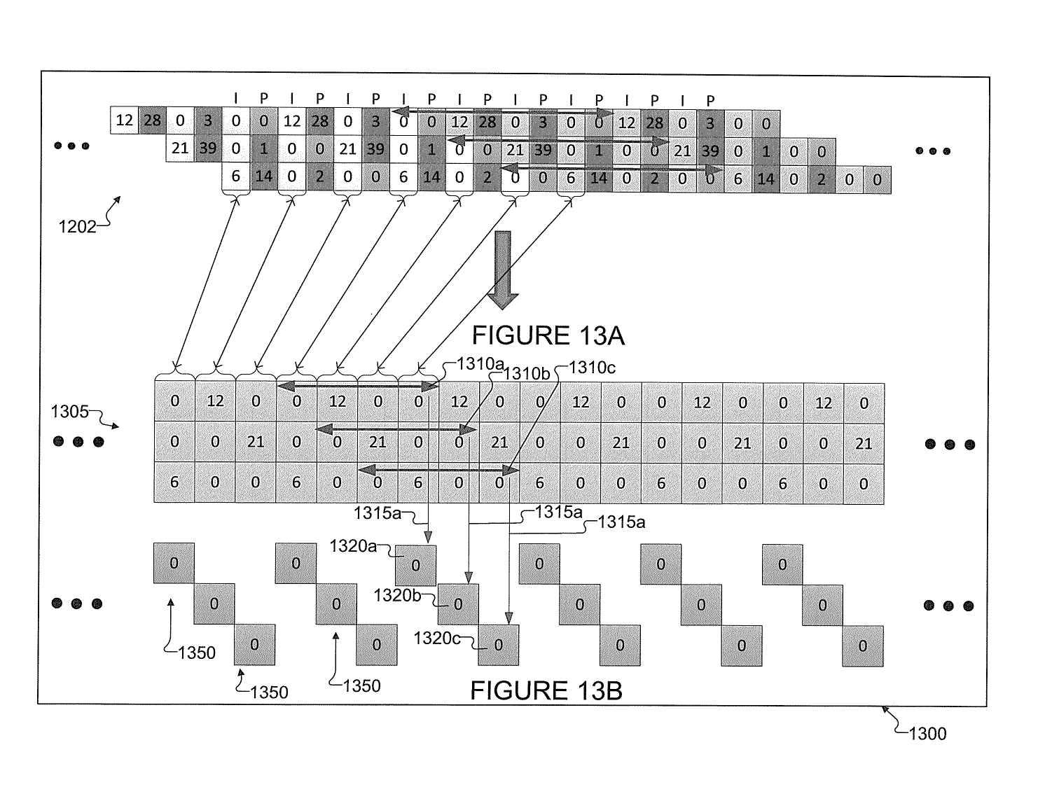

In blocks 715-730, the QC-RSC encoder 500 transforms the SC-LDPC base code into a Trellis-based Quasi-Cyclic LDPC (TQC-LDPC) convolutional code. In order to transform the SC-LDPC base code into a PC-LDPC convolutional code, the QC-RSC encoder 500 derives an SC-LDPC code based on the SC-LDPC base code (shown in part (a) of FIG. 12) (block 715), serializes and concatenates the derived SC-LDPC code into a concatenated SC-LDPC encoding structure (shown respectively in parts (b) and (c) of FIG. 12) (block 720), excludes previous parity bits of other rows from a next parity calculation (shown in FIG. 13A) (block 725), and separates systematic bits from parity bits, yielding a derived TQC-LDPC convolutional code (shown in FIG. 13B) (block 730).

In addition to transforming the SC-LDPC base code into a Parallel Concatenated Trellis-based Quasi-Cyclic LDPC (PC-LDPC) convolutional code, the QC-RSC encoder 500 is configured to select: (i) whether to generate a modified TQC-LDPC convolutional H-matrix; (ii) whether to perform relative shifting; (iii) whether to puncture one or more rows, and (iv) whether to implement a Dual-Step PC-LDPC Convolutional code. When the QC-RSC encoder 500 selects to generate a modified TQC-LDPC convolutional H-matrix, the process 700 proceeds to block 735, otherwise, the process skips block 735 and proceeds to block 740. When the QC-RSC encoder 500 selects to perform relative shifting, the process 700 proceeds to block 740, otherwise, the process skips block 740 and proceeds to block 745. When the QC-RSC encoder 500 selects to implement a Dual-Step PC-LDPC Convolutional code, the process 700 proceeds to block 745, otherwise, the process skips block 745 and proceeds to block 750.

In block 735, the QC-RSC encoder 500 generates a modified TQC-LDPC convolutional H-matrix (shown in FIGS. 14-15). More particularly, the QC-RSC encoder 500 changes the quasi-cyclic values in order to generate the modified TQC-LDPC convolutional H-matrix.

In block 740, the QC-RSC encoder 500 performs relative shifting by using one row as a reference row while shifting the remainder of the rows. More particularly, the QC-RSC encoder 500 selects a reference row, such as first row or other row. All shift entries of the reference row are “0” to denote the unity matrix. The QC-RSC encoder 500 shifts each other row relative to the selected reference row.

In block 745, the QC-RSC encoder 500 determines a QC-Shift Dual-Step TQC-LDPC Convolutional Code.

In block 750, the QC-RSC encoder 500 outputs a PC-LDPC convolutional code. More particularly, the QC-RSC encoder 500 generates each row of parity (J) in Z-group bits in parallel and selects which row parity bits to output. For example, the QC-RSC encoder 500 can select to output one parity per column (shown in FIG. 13B), two parity per column (shown in FIGS. 14 and 16), or any number of parity up to the column rate (Wc) of the SC-LDPC base code.

As part of outputting parity, in response to a selection to perform puncturing, the QC-RSC encoder 500 punctures one or more rows of parity. More particularly, the QC-RSC encoder 500 increases the output rate (R) by performing a puncturing operation. In certain embodiments, the QC-RSC encoder 500 punctures according to a puncturing pattern.

FIG. 7B illustrates a PC-LDPC decoding process 701 according to this disclosure. While the flow chart depicts a series of sequential steps, unless explicitly stated, no inference should be drawn from that sequence regarding specific order of performance, performance of steps or portions thereof serially rather than concurrently or in an overlapping manner, or performance of the steps depicted exclusively without the occurrence of intervening or intermediate steps. The process depicted in the example depicted is implemented by encoder circuitry or processing circuitry in a transmitter such as, for example, in a base station. For simplicity, this disclosure will be described in the context of an example scenario in which the decoder 600 implements the PC-LDPC decoding process 701.

In block 755, the TQC-LDPC MAP decoder 600 receives a Parallel Concatenated Trellis-based Quasi-Cyclic LDPC (PC-LDPC) convolutional code in a form of an H-matrix. The PC-LDPC) convolutional code can be punctured or un-punctured. The H-matrix includes a systematic submatrix (H_{sys}) of the input systematic data and a parity check submatrix (Hₚₐᵣ) of parity check bits. The PC-LDPC convolutional code is characterized by a lifting factor (Z). The Hₚₐᵣ includes a column of Z-group parity bits concatenated with each column of systematic bits, and the Hₚₐᵣ includes J parity bits per systematic bit.

In blocks 760-775, the decoder decodes the received PC-LDPC convolutional code 610 into and a group (x_{z}(n)) 635 of Z systematic bits. The decoder performs blocks 760-775 for each Z-row of the PC-LDPC convolutional code 610.

In block 760, the TQC-LDPC MAP decoder 600 determines, from the PC-LDPC convolutional code, a specific quasi-cyclical domain of the Z-row that is different from any other quasi-cyclical domain of another Z-row of the PC-LDPC convolutional code.

In block 765, the TQC-LDPC MAP decoder 600 selectively quasi-cyclically shifts the bits of the Z-row by the specific quasi-cyclical domain. That is, the decoder 600 selects to omit quasi-cyclically shifting the bits of a first Z-row based on a determination that the first Z-row is all cyclical shifts of zero. Otherwise, the decoder 600 selects to perform the quasi-cyclically shifting of the bits of the first Z-row.

In block 770, the TQC-LDPC MAP decoder 600 performs Z parallel MAP decoding processes on the shifted bits of the Z-row.

In block 775, the TQC-LDPC MAP decoder 600 un-shifts the parallel decoded bits of the Z-row by the specific quasi-cyclical domain, yielding the group (x_{z}(n)) of Z systematic bits.

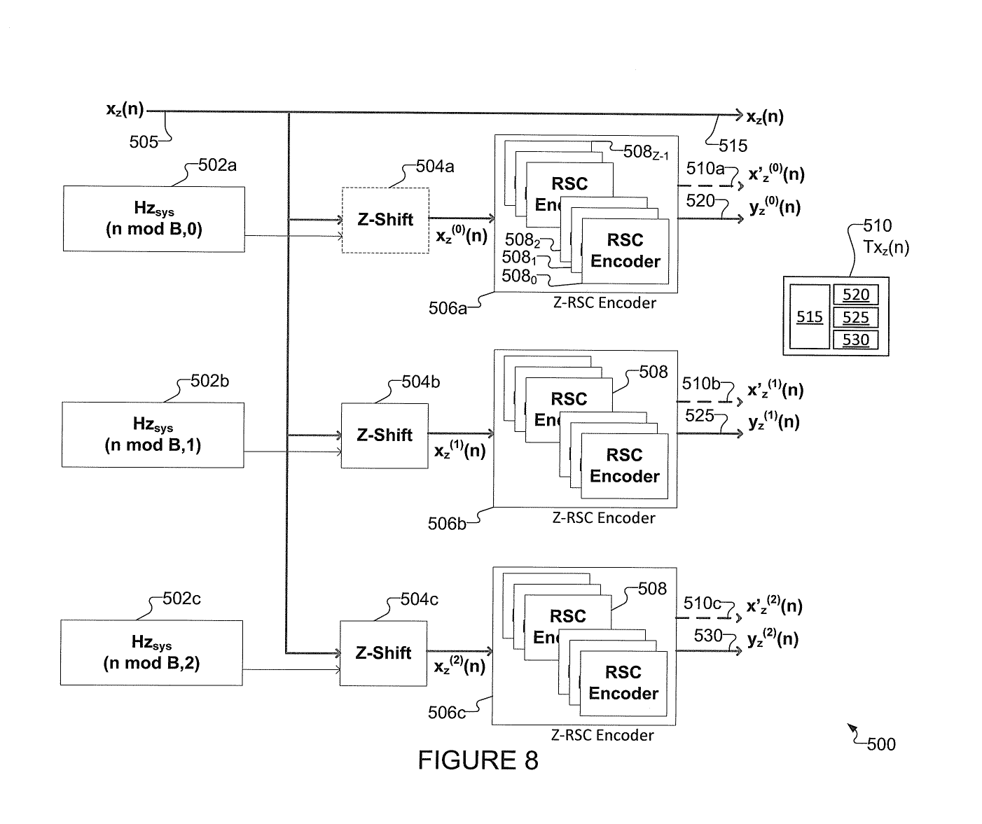

FIG. 8 illustrates the QC-RSC encoder 500 of FIG. 5 in more detail according to this disclosure. The example QC-RSC encoder 500 has an underlying parity check matrix (PCM) H with J=3 Z-rows. The QC-RSC encoder 500 includes a set of J row identifiers 502a-502c (generally referred to by reference number 502), namely, one row identifier per Z-row of the underlying PCM H, wherein each row identifier stores H_{z}_{_{sys}}^{T}(n mod B,j). The first Z-row identifier 502a stores H_{z}_{_{sys}}(n mod B, 0); the second Z-row identifier 502b stores H_{z}_{_{sys}}^{T}(n mod B, 1); and the third Z-row identifier 502a stores H_{z}_{_{sys}}^{T}(n mod B, 2).

The QC-RSC encoder 500 includes a set of J quasi-cyclic shifters 504a-504c (generally referred to by reference number 504), namely, one quasi-cyclic shifter per Z-row of the underlying PCM H. Each quasi-cyclic shifter 504 includes a multiplier that outputs the product of its two input values. That is, each quasi-cyclic shifter 504 receives the input 505 x_{z}(n), receives input H_{z}_{_{sys}}^{T}(n mod B, j) from the row identifier 502a-502c of a corresponding Z-row, and outputs x_{z}^{(j)}(n). The first quasi-cyclic shifter 504a outputs x_{z}⁽⁰⁾(n); the second quasi-cyclic shifter 504a outputs x_{z}⁽¹⁾(n); and the third quasi-cyclic shifter 504a outputs x_{z}⁽²⁾(n).

The QC-RSC encoder 500 includes a set of J Z-RSC encoders 506a-506c (generally referred to by reference number 506), namely, one Z-RSC encoder per Z-row of the underlying PCM H. Each Z-RSC encoder 506 includes a Z-RSC encoder set, namely, a group of Z RSC encoders 508 (individually referred to by reference numbers 508₀, 508₁, 508₂, . . . , 508_{z-1}) that encode the input bit set x_{z}^{(j)}(n) through the j-th Z-RSC encoder set. In an example where the lifting factor is Z=42, the first Z-RSC encoder 506a includes 42 RSC encoders 508 within a first Z-RSC encoder set; the second Z-RSC encoder 506b includes 42 RSC encoders 508 within a second Z-RSC encoder set; and the third Z-RSC encoder 506c includes 42 RSC encoders 508 within a third Z-RSC encoder set. Each Z-RSC encoder 506 receives an input, which is the output x_{z}^{(j)}(n) from a quasi-cyclic shifter 504 of a corresponding Z-row. Each Z-RSC encoder 506 outputs a Z-group of parity bits y_{z}^{(j)}(n) corresponding to its Z-row. More particularly, the first, second, and third Z-RSC encoders 506a, 506b, and 506c respectively output the first second and third Z-group of parity bits 515, 520, and 525. Each Z-RSC encoder set consists of Z identical RSC, where each RSC encoder 508 encodes a single bit (out of the Z input bits) at a time. That is, each Z-RSC encoder 506 is configured to encode Z input bits in parallel (i.e., at the same time), wherein each RSC encoder 508 encodes one of the Z input bits. That is, each Z-RSC encoder 506 provides a different input bit from the Z input bits of x_{z}^{(j)}(n) to a different RSC encoder 508.

In a non-limiting example, the first, second, and third row identifiers 502 respectively provide a value of 30, 21, and 41 to its corresponding shifter 504. The first Z-RSC encoder 506a provides the first bit of x_{z}⁽¹⁾(n) to the thirtieth RSC encoder 508₂₉, provides the twelfth bit of x_{z}⁽¹⁾(n) to the forty-second RSC encoder 508₄₁, and provides the thirteenth bit of x_{z}⁽¹⁾(n) to the first RSC encoder 508₀. In the 30^{th} permutation matrix of a set of 42 permutation matrices, the last row includes a value at the twelfth bit, which corresponds to the difference between the lifting factor (Z=42) and the value (n=30) output from the first row identifier 502a, and thus the first row includes a value at the thirteenth bit. The second Z-RSC encoder 506b provides the first bit of x_{z}⁽¹⁾(21) to the twenty-first RSC encoder 508₀. The third Z-RSC encoder 506c provides the first bit of x_{z}⁽¹⁾(41) to the forty-first RSC encoder 508₄₀.

According to REF12, y=E(x) where y and x are the output and input of a single bit Recursive Systematic Convolutional (RSC) encoder, respectively. As described above, each RSC encoder 508 receives one row of the quasi-cyclically shifted input, which includes one bit. Accordingly, the output y_{z}^{(j)}(n) of an Z-RSC Encoder 506 can be expressed as E_{z}^{(j)}(x_{z}^{(j)}(n)). The j-th set of Z convolutional encoders E(x) corresponds to input x_{z}^{(j)}(n), where the j-th convolutional encoder set corresponds to the j-th Z-row in H_{z}_{_{sys}} matrix out of J Z-rows. Hence, the j-th Z-group output parity bit set y_{z}^{(j)}(n) is defined by Equation 5:

y_{z}^{(j)}(n)=E_{z}^{(j)}(x_{z}^{(j)}(n)) (5)

The systematic set x_{z}(n) of the input 505 is the output 515 from the QC-RSC encoder 500 unchanged, as performed in other systematic codes (e.g., QC-LDPC codes and Turbo codes[0039]) (described in REF12). Alternatively, the encoder 500 can output a cyclically shifted Z-RSC systematic output set 510a, 510n, or 510c instead of outputting the unchanged set 515. The systematic output set x′_{z}^{(j)}(n) can be derived from any of the cyclically shifted Z-RSC systematic output sets x′_{z}^{(j)}(n), j=0, . . . , J−1=2. The output set x′_{z}^{(j)}(n) is significant in the case of terminated codes during tail bit period, where each RSC encoder 508 outputs its tail information to enable proper code termination (e.g., reaching state “0”). The parity bit set y_{z}^{(j)}(n), j=0, . . . ,J−1=2 is obtained from the quasi-cyclic shifted input set x_{z}^{(j)}(n) to the j-th Z-RSC encoder set. The quasi-cyclic shift value for x_{z}^{(j)}(n) is obtained from the corresponding Z-row j of the underlying PCM systematic part H_{z}_{_{sys}}. In the case of non-existent shift value in the underlying PCM where H_{z}_{_{sys}}(j,l)=−1, no encoding is performed for the corresponding input set x_{z}(n). In such embodiments, the first Z-row cyclic shift operation 504a can be omitted (shown by the dashed line) if the underlying PCM first row is all 0 values. Zero values denote un-shifted identity sub-matrices.

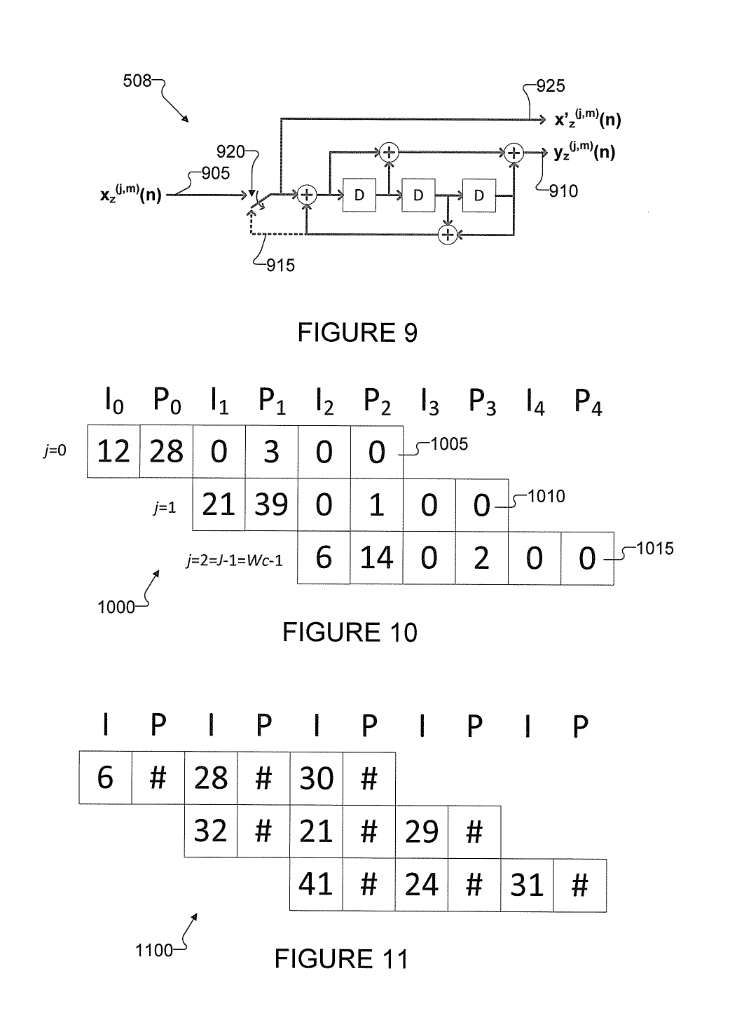

FIG. 9 illustrates a Recursive Systematic Convolutional (RSC) encoder 508 according to this disclosure. The embodiment of the RSC encode 508 shown in FIG. 9 is for illustration only. Other embodiments could be used without departing from the scope of the present disclosure.

The example RSC encoder 508 corresponds to a constraint length of δ=4. The RSC encoder 508 provides an output 910 that corresponds to a single input bit 905 x_{z}^{(j,m)}(n),m∈{0, . . . ,Z−1} from the n-th Z-group of cyclically shifted input bit set x_{z}^{(j)}(n) when passed through the m-th RSC encoder 508 in the j-th Z-RSC encoder set 506. The dotted line depicted represents the tail bits 915 processing at the end of the block in case of a finite stream. In this case, the input bits to the RSC encoder are disconnected (shown by opening of the switch 920), while the RSC encoder shift register is flushed and the outputs of both x′_{z}^{(j,m)}(n) 925 and y_{z}^{(j,m)}(n) 910 are sent to the corresponding decoder 600. The purpose of the tail bits 915 is to “bring” the finite state of the RSC encoder 508 to the all “0” state. The all “0” state at the end of the block encoding process allows the decoder 600 to terminate at a specified state (i.e., specified to both encoder 500 and decoder 600) at the end of the block.

The RSC encoder 508 uses the various polynomials expressed by Equations 6-8 to perform encoding.

$$\begin{matrix}G ( D ) = [ 1 , \frac{{g}_{1} ( D )}{{g}_{0} ( D )} ] & ( 6 ) \\ {g}_{0} ( D ) = 1 + {D}^{2} + {D}^{3} & ( 7 ) \\ {g}_{1} ( D ) = 1 + D + {D}^{3} & ( 8 )\end{matrix}$$

The polynomials g₁(D) and g₀(D) are the feed-forward polynomial (numerator) and the feedback polynomial (denominator) respectively of an individual RSC encoder 508. Equations 9 and 10 express the individual RSC encoder polynomials, where g₀^{(k)} and g₁^{k} are the k-th location in the binary vector (of length δ) representation (over GF(2)) of g₀(D) and g₁(D) respectively, and δ is the constraint length (CL) of the code. Therefore, the RSC encoded parity bits, yᵢ, can be generated from input information bits, xᵢ, as yᵢ=E(xᵢ)=Σₖ₌₀^{δ-1}g₁^{(k)}aᵢ₋ₖ, aᵢ=Σₗ₌₀^{δ-1}g₀^{(l)}xᵢ₋ₗ. Each polynomial has a degree δ−1 with gᵢ^{(δ-1)}=1, i=0,1 and gᵢ⁽⁰⁾=1, i=0,1 which corresponds to the current input bit. Otherwise, the effective degree (thus constraint length) is reduced. An example of an RSC encoder polynomial, G(D), obtained from Long Term Evolution (LTE) Standard (See REF4) with constraint length δ=4

g₀(D)=Σₖ₌₀^{δ-1}g₀^{(k)}D^{k} (9)

g₁(D)=Σₖ₌₀^{δ-1}g₁^{(k)}D^{k} (10)

Although ensuring a specified state at the end of the block results in a marginal rate reduction, it reduces the decoding BER/FER compared to an unterminated code. As described more particularly below, a sliding window decoding method associated with the PC-LDPC convolutional codes does not require code termination to obtain a low BER. The input granularity, δ, to the QC-RSC encoder 500 is retained as δ=Z bits and the output rate of the unterminated TQC-LDPC RSC Encoder is R_{base}=(1+J)⁻¹. The output rate can be increased through puncturing, as shown in FIGS. 15 and 17.

FIG. 10 illustrates an example of a Spatially-coupled Low Density Parity Check (SC-LDPC) base code according to this disclosure. The embodiment of the SC-LDPC base code 1000 shown in FIG. 10 is for illustration only. Other embodiments could be used without departing from the scope of the present disclosure.

The capacity-approaching spatially-coupled (SC) LDPC code can be designed based on the process described in REF2. The encoder 500 transforms the designed SC-LDPC base code 1000 Parallel-Concatenated Trellis-based Quasi-Cyclic LDPC (PC-LDPC) convolutional code. The transformation to a trellis-based code enables use of trellis-based encoders, such as the QC-RSC encoder 500 along with the associated capacity-approaching trellis-based decoders, such as the MAP decoder 600.

The SC-LDPC code 1000 is derived from a (3,6) regular LDPC code through the process described in REF2. The encoder 500 selects the lifting factor of the code to be Z=42 (similar to IEEE802.11ad in REF8). The numbers in each entry denote the quasi-cyclic shift of the corresponding identity sub-matrix of size Z×Z.

The encoder 500 constructs the SC-LDPC code 1000 to included Systematic (I) and Parity (P) pairs. For every set of Z=42 input systematic bits, there are equal number of parity bits added to obtain the final codeword resulting in a code rate R=1/2. For the first set of Z=42 input systematic bits, the first Z-row is employed to generate the first set of parity bits. Then, for the second set of Z=42 input systematic bits, the second Z-row is employed to generate the second set of parity bits. For the third set of Z=42 input systematic bits, the third Z-row is employed to generate the third set of parity bits. The first Z-row is employed again for the fourth set of input systematic bits, and so on for the rest of the input sets. Note that although any parity set is obtained using a certain Z-row, it is then used in all Z-rows together with the corresponding systematic bits to obtain the next sets of parity bits. The row weight Wr of the SC-LDPC code 1000 is maintained at 6, and the maximum column weight Wc equals 3, although not all the columns have this weight. For example, the column weight of the first and last I/P pairs {I₀,P₀} and {I₄,P₄} equals 1; the column weight of the second and penultimate I/P pairs {I₁,P₁} and {I₃,P₃} equals 2; and the column weight of the middle I/P {I₂,P₂ } is 3. The SC-LDPC code 1000 is characterized as a (3,6) base LDPC code corresponding to the (Wc,Wr). As discussed more particularly below, the SC-LDPC code 1000 (which is identical to each of the base codes 1000a-1000d of FIGS. 12 and 13A) can include significant parity 1005, 1010, 1015 at least at the following (row, column) locations: (0, P₂) and (1, P₃) and (1, P₄).

FIG. 11 illustrates another example of an SC-LDPC base code 1100 according to this disclosure. The systematic bits of the SC-LDPC base code 1100 correspond to the modified TQC-LDPC convolutional code 1400 in FIG. 14. The parity bits are represented by number signs (#), as the parity bits are excluded as part of the transformation of the SC-LDPC base code 1100 to the modified TQC-LDPC convolutional code 1400.

FIG. 12 illustrates a transformation of an SC-LDPC base code to an SC-LDPC code, to a serialized SC-LDPC code, to a concatenated SC-LDPC encoding structure according to this disclosure. The embodiment of the transformation shown in FIG. 12 is for illustration only. Other embodiments could be used without departing from the scope of the present disclosure.

In part (a) of FIG. 12, the encoder 500 repeats the SC-LDPC base code 1000 to construct a final (3,6) SC-LDPC code PCM H 1200. The base code repetition is performed to generate the parity bit sets for the next systematic bit sets. For the SC-LDPC base code 1000, the first Z-row of the second base code 1000b (non-shaded) is positioned to start on the 7-th column to form a continuation to the first Z-row of the first base code 1000a (faintly shaded). The first Z-row of the third base code 1000c (darkly shaded) is positioned to started on the 13^{th} column to form a continuation to the first Z-row of the second base code 1000b. The first Z-row of the fourth base code 1000d (lightly shaded) is positioned to started on the 19^{th} column to form a continuation to the first Z-row of the third base code 1000c.

The SC-LDPC code PCM H 1200 is a regular LDPC code with Wr=6 and Wc=3 for all rows and columns, respectively. The generated SC-LDPC code 1200 can be terminated on both sides as described in REF2. In other words, where k represents Wc and n represents Wr, a (k,n) regular SC-LDPC code of block size N and lifting factor Z, then the number, N_{ZRow}_{_{sc}}, of the unterminated PCM H Z-rows is defined by Equation 11:

$${N}_{{ZRow}_{SC}} = \frac{( 1 - \frac{k}{n} ) N}{Z} = \frac{( n - k ) N}{nZ} \qquad ( 11 )$$

The (k,n) SC-LDPC code 1200 has a repetition period every n columns with alternating systematic and parity columns (B=n/2). Since H is a block diagonal matrix, the first trellis-based transformation step is to serialize H. The serialization process reduces the effective number of Z-rows in the modified parity check matrix, to only J=k Z-rows in the serialized LDPC code parity check matrix. The modified PCM H′ is obtained by adding the underlying H row sets as defined in Equation 12:

$$\begin{matrix}{H}_{{Z}_{sys}}^{′} ( j , l ) = {\sum }_{s = 0}^{\frac{{N}_{{ZRow}_{SC}}}{k} - 1} {H}_{{Z}_{sys}} ( sk + j , l ) , & ( 12 ) \\ j ∈ \{ 0 , … , J - 1 \} , l ∈ [ - ∞ , ∞ ] & \end{matrix}$$

In part (b) of FIG. 12, the encoder 500 performs (3,6) SC-LDPC code Serialization 1201. Part (b) of FIG. 12 shows the result of the serialization and the concatenation process on the (3,6) SC-LDPC code 1000.

The (k,n) SC-LDPC code is a regular code with quasi-cyclic value repetition period every n columns with alternating systematic and parity columns. The encoder 500 can expand the code beyond the N columns of the underlying SC-LDPC by concatenating H 1200 to obtain the streaming form of the concatenated SC-LDPC code. Even though the block diagonal parity check matrix H 1200 of the (3,6) SC-LDPC block code 1000 was transformed to a streaming code, the SC-LDPC encoding structure is maintained. That is, the code 1201 is not yet considered a trellis-based code because each parity bit depends on previous parity bits generated in other rows. For example, the parity bits calculated in the first row are dependent on three previous systematic bits and two previous parity bits from the two other rows.

In part (c) of FIG. 12, the encoder 500 constructs a concatenated (3,6) SC-LDPC Encoding Structure 1202.

The significant parity generated in each row from prior (n-1) columns is shown. The significant parity of the first row are in columns 5, 11, 17, and 23; significant parity of the second row are in columns 7, 13, 19, and 25; and the significant parity of the third row are in columns 9, 15, 21, and 27. That is, each base code 1000a-1000d includes significant parity for each row. Once the (3,6) streaming SC-LDPC code is obtained, the encoder converts the code 1201 to a trellis-based LDPC convolutional code 1202. The encoder 500 first separates the systematic portion (I) and the parity portion (P) of the streaming PCM. The systematic bits are then concatenated together while generating the parity bits. The parity bit sets are then modified to be generated from convolutional encoding (i.e., RSC encoder 508) to derive the final Parallel Concatenated TQC-LDPC (PC-LDPC) convolutional code. The derived PC-LDPC convolutional code has a fine input granularity, δ, which is defined as the minimum number of input information bits the code requires to generate a codeword, and equals to Z.

FIG. 13 illustrates a process 1300 of generating a column of parity bits for a Parallel Concatenated Trellis-based Quasi-Cyclic Low Density Parity Check (PC-LDPC) convolutional code having an output rate of ½ from a concatenated SC-LDPC encoding structure having a separation of systematic bits from parity bits according to embodiments of this disclosure. The embodiment of the process 1300 shown in FIG. 13 is for illustration only. Other embodiments could be used without departing from the scope of the present disclosure.

FIG. 13A illustrates the trellis-based LDPC convolutional code 1202, where non-significant parity bits are marked (darkly shaded) for exclusion from the PC-LDPC convolutional code. For example, each base code 1000a-1000d within coder 1202 excludes the non-significant parity bits. The encoder 500 extracts each column of the concatenated (3,6) SC-LDPC Encoding Structure 1202 that actually exhibits the full column weight Wc=3 and concatenates the extracted columns to construct the systematic bit set 1305. The encoder 500 generates a column of parity 1350 for each row of the systematic bit set 1305.

FIG. 13B illustrates an example of the derived PC-LDPC convolutional code once the systematic bits are concatenated. A Z-column of parity bit set is attached to every Z-column of systematic bit set creating a code rate R=1/2 through convolutional encoding (with constraint length of λ=4). Both the systematic and parity quasi-cyclic values are retained the same as the underlying (3,6) SC-LDPC code with Z=42.

The horizontal arrow 1310a-1310c of each row spans), λ=4 columns, which represents the PC-LDPC encoding operation of wherein 3 (i.e., n−1, where n=4) previous systematic values are used to generate the parity of n^{th} column. For example, in the first row, [0 12 0] systematic values are used to generate the parity [0] of the 4^{th} column; in the second row, [0 21 0] systematic values are used to generate the parity [0] of the 4^{th} column; and in the third row, [0 6 0] systematic values are used to generate the parity [0] of the 4^{th} column.

The each encoding process horizontal arrow 1310a-1310c corresponds to a vertical arrow 1315a-1315c of the parity of n^{th} column. The vertical arrow 1315a-1315c represents the encoder 500 generating the parity 1320a to be concatenated with the systematic values.

FIG. 14 illustrates a process 1400 of generating a column of parity bits for a modified TQC-LDPC convolutional code having an output rate of ⅓ according to embodiments of this disclosure. The embodiment of the process 1400 shown in FIG. 14 is for illustration only. Other embodiments could be used without departing from the scope of the present disclosure. Note, the encoding function represented by the horizontal lines 1310a-1310c and vertical lines 1320a-1320c for generating parity 1320a-1320c per column 1350 can be the same as or similar to the encoding function represented by the horizontal lines 1410a-1410d and vertical lines 1420a-1420d for generating parity 1420a-1420d per column 1450.

Once the PC-LDPC convolutional code 1305 is derived from the SC-LDPC code 1000, the quasi-cyclic values may be altered to reduce the BER. An example of the modified quasi-cyclic values, while retaining the lifting factor, Z=42, is provided in FIG. 14. The new quasi-cyclic values [30 6 28] replace the [0 12 0] values and apply to the corresponding systematic sets as well as the parity sets (same quasi-cyclic shift values). Different quasi-cyclic shift values can be applied for the corresponding systematic sets and parity sets. However, choosing different shift values increases the encoder and decoder complexities. The repetition rate (or periodicity) of B=3 of Z-group systematic bit sets is retained as the underlying SC-LDPC code systematic periodicity. A similar TQC-LDPC convolutional conversion method can also be applied to other rates. In certain embodiments, encoder 500 uses the modified TQC-LDPC convolutional code 1405 to output one parity 14151-1415c per column (i.e.,

$$[ \begin{matrix}30 & . & . \\ . & 29 & . \\ . & . & 31\end{matrix} ] ) ,$$

yielding a rate R=1/2. In other embodiments, the encoder uses the modified TQC-LDPC convolutional code 1405 to output an additional parity 1420d per column (i.e.,

$$[ \begin{matrix}30 & 6 & . \\ . & 29 & 32 \\ 41 & . & 31\end{matrix} ] ) ,$$

yielding a modified PCM with R=1/3. The R=1/3 TQC-LDPC convolutional PCM retains the structure of the R=1/2 PCM, however, twice as many parity bits as in the case of R=1/2 code are output from the encoder 500 at a time.

In the systematic bit set 1405 of FIGS. 14-15, the code periodicity B=3 is retained throughout the transformation. Similar to block codes where increasing the block size can lead to BER reduction, even in TQC-LDPC convolutional codes (i.e., PC-LDPC convolutional codes); increasing B reduces the periodicity and can further reduce the BER of the code. Example methods to increase B include: the single step PC-LDPC encoding method 700 without blocks 740 or 745, the dual-step PC-LDPC encoding method 700 with block 745, and the PC-LDPC encoding method 700 including the permutation method of block 740. The single step PC-LDPC encoding method 700 increases the number of Z-columns compared to the underlying LDPC systematic parity check matrix (H_{z}_{_{sys}}).

FIG. 15 illustrates a process 1500 of puncturing by applying a puncturing pattern to the modified TQC-LDPC convolutional code having an output rate of ½ of FIG. 14 according to embodiments of this disclosure.

The encoder 500 implements a method of reducing BER by performing puncturing wherein the third row is not used for R=1/2. For example, the column 1550 of parity output from the encoder 500 has two rows instead of three. Instead of using the nth row of systematic bits [31 41 24] to generate parity for the nth row, the encoder 500 uses the n-1 systematic bits [32 21 29] of the second row to generate the third parity 1520.

FIG. 16 illustrates a process 1600 of reducing periodicity while generating a column of parity bits for an example modified TQC-LDPC convolutional code having an output rate of ⅓ according to embodiments of this disclosure. The embodiment of the process 1600 shown in FIG. 16 is for illustration only. Other embodiments could be used without departing from the scope of the present disclosure.

The encoder 500 can increase the periodicity beyond B=3 to a higher value (e.g., B=6 and beyond) to further reduce the BER. For example, similar to the systematic bit set 1305 having B=3, the systematic bit set 1605 having B=3. Increasing B also increases the Z-Shift complexity since it increases the number of shifting options for each Z-row. According to REF13, increasing the shifting options increases the encoder/decoder critical path latency and die area, which reduces the throughput and increases power consumption respectively. The input granularity δ remains Z.

FIG. 17 illustrates a process 1700 of reducing periodicity and puncturing by applying a puncturing pattern to the modified TQC-LDPC convolutional code of FIG. 16 having an output rate of ½ according to embodiments of this disclosure. The process 1700 is similar to the process 1500 of FIG. 15.

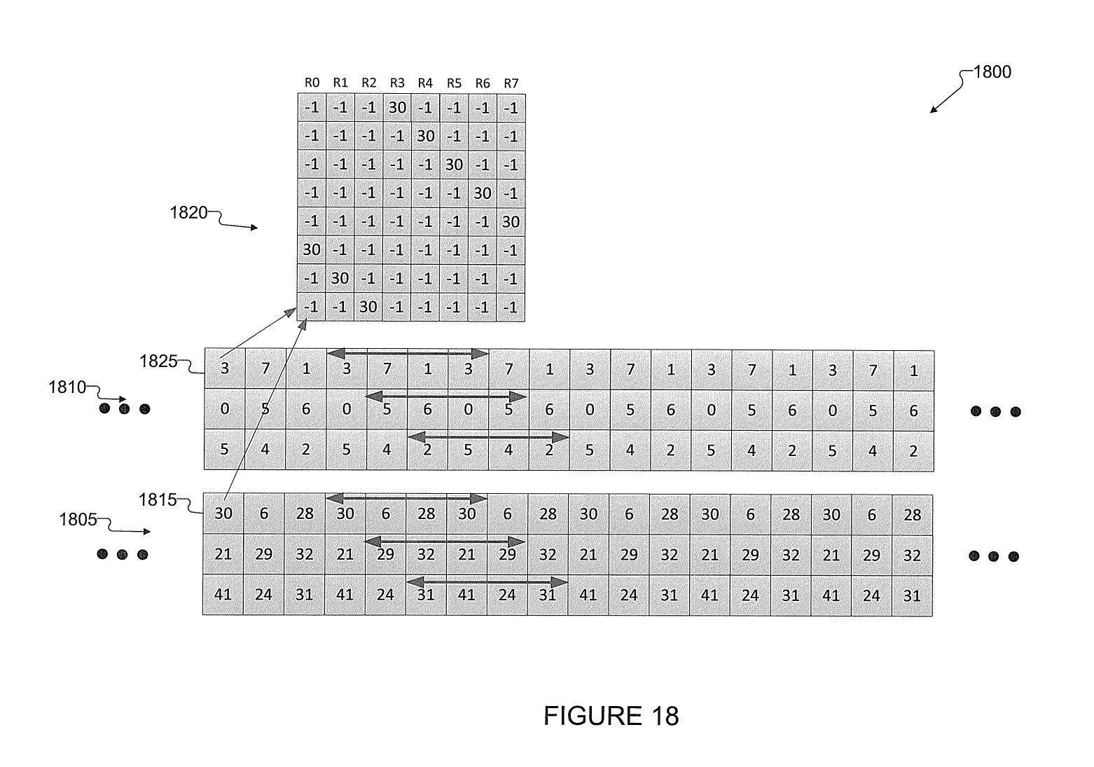

FIG. 18 illustrates a Dual-Step PC-LDPC convolutional code 1800 according to embodiments of this disclosure. The embodiment of the Dual-Step PC-LDPC convolutional code 1800 shown in FIG. 18 is for illustration only. Other embodiments could be used without departing from the scope of the present disclosure.

In REF5, an algorithm (namely Dual-Step) is proposed for deriving an LDPC block code family with code length Zp×N, where N is the base-family LDPC block code-length and Zp is a second level (step) lifting factor, over the original Z lifting factor, that is applied to the base-family to increase the block size. The algorithm in REF5 preserves the properties of the base-family: the new LDPC code family inherits its structure, threshold, row weight, column weight, and other properties from the base-family. In addition, the number of non-zero elements in the new codes increases linearly with Zp, however, the decoding complexity per bit remains the same. The Zp Quasi-Cyclic shift method 1800 expands the Z sets Zp times by applying a second level of Zp cyclic shifts. As an example of Zp=8, the encoder 500 applies the Zp Dual-Step Quasi-Cyclic Shift method 1800 to the TQC-LDPC convolutional code.

Each entry in the base PCM 1805 is lifted (or expanded) by Zp=8. The values in the upper matrix 1810 denote the cyclic right shift to be applied to the base PCM entry. In this example, the PCM entry 1815 having a value of “30” is lifted again by the second level lifting factor Zp=8 of the matrix 1820 and is cyclically shifted by the corresponding entry 1825 having a value of “3”. That is, the entries 1815 and 1825 correspond to each other by having a same location within their respective matrices 1805 an 1810. Hence the dual-step method input granularity requirement is δ_{DS}=Zp×Z.

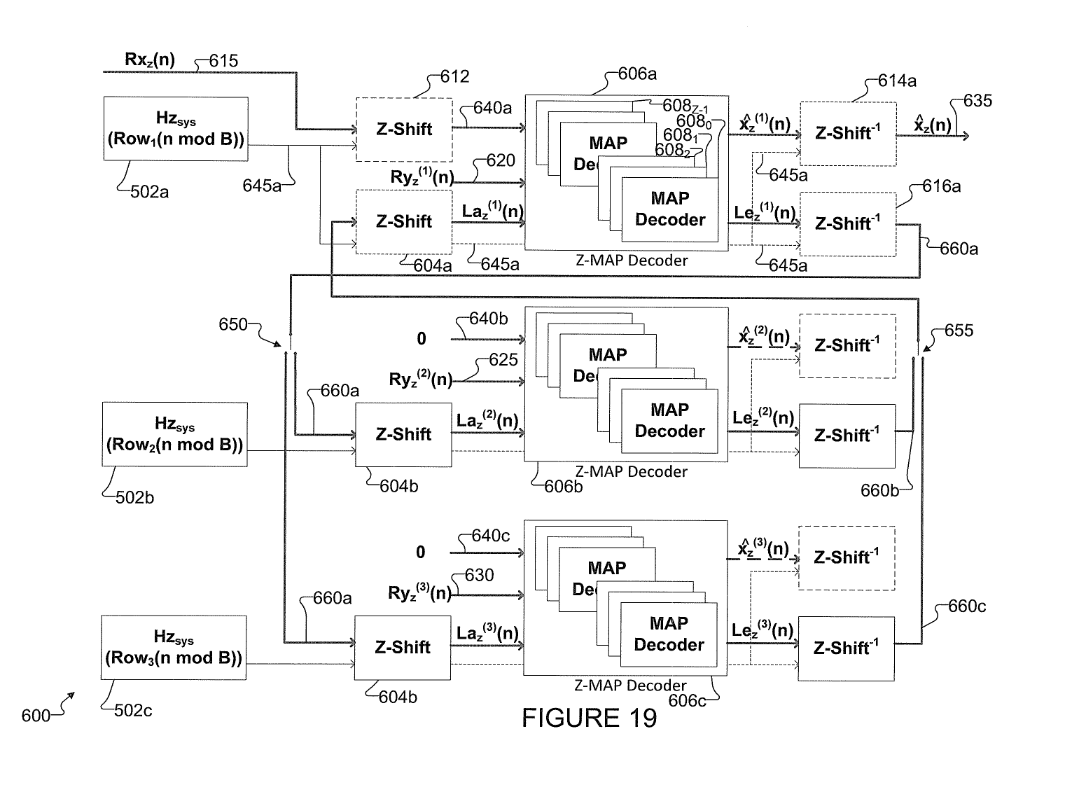

FIG. 19 illustrates the TQC-LDPC MAP decoder 600 of FIG. 6 in more detail according to this disclosure. The QC-MAP decoder architecture 600 includes a set of J row identifiers 502a-502c identical to the row identifiers of the encoder 500. The first row includes two quasi-cyclic shifters 604a and 612 that each receives the same input (i.e., a value of n) from the corresponding row identifier 502a of the first row. The shifter 612 outputs Z soft decision LLRs 640a for each bit of the input 615. During a first iteration, prior to inputting any information into the Z-MAP decoder 606a, the shifter 604a is configured to output an a-priori LLR of decoded bits La_{z}⁽¹⁾(n) based on an a null input. For each iteration (i.e., excluding the first iteration), the shifter 604a forwards the quasi-cyclic shift value 645a from the row identifier 502a to corresponding un-shifters 616a and 614a of the same row. The QC-MAP decoder architecture 600 includes a set of J Z-MAP decoders 606a-606c, each of which includes a Z-MAP decoders 608 (individually referred to by reference numbers 608₀, 608₁, 608₂, . . . , 608_{Z-1}). Each Z-MAP decoder 608 receives three inputs 640a, 620, and La_{z}^{(j)}(n) and generates two outputs, namely, a decoded version of the received 615 information x and a set of Z extrinsic LLR values Le_{z}^{(j)}(n) corresponding to each a-priori bit La_{z}^{(j)}(n). The un-shifters 614a, 616a reverse the quasi-cyclic shift that occurred in the shifters 612 and 604, respectively.

Each other row includes one quasi-cyclic shifter 604a-604b that receives an input from a corresponding row identifier 502b-502c. Each other row includes other components that function in a same or similar manner as the first row components. The switch 650 of the decoder 600 enable each other row to selectively (e.g., upon convergence of the \hat{x}_{z}⁽¹⁾(n) value with the Le_{z}⁽¹⁾(n) value) receive and decode a current un-shifted set of Z extrinsic LLR values Le_{z}(n) 660a. The switch 655 of the decoder 600 enable each other row to selectively provide feedback of a set of Z extrinsic LLR values 660b, 660c to any other shifter 604a of a same or different row.

The QC-MAP decoder architecture 600 is based on the TQC-LDPC MAP (QC-MAP) decoder relations, which can be expressed by a set of equations including Equation (14). The first row Z-Shift 604 and 610 can be omitted if the first row of the PCM is all cyclic shifts of 0 (i.e., not shifted).

The decoder LLR input 610 is grouped similar to the encoder output 510, in Z-group LLRs of the systematic bit set, Rx_{z}(n) 615, and three corresponding parity bit sets, Ry_{z}⁽⁰⁾(n), Ry_{z}⁽¹⁾(n), Ry_{z}⁽²⁾(n). Each Z-MAP decoder 606a-606c set out of the three Z-MAP decoder sets processes the corresponding received LLR set input at different interleaved domain determined by the corresponding H _{z}_{_{sys}} Z-row. Each Z-MAP decoder set consists of Z parallel MAP decoders. As shown in FIG. 13, a three sequential transmissions

$$\{ [ \begin{matrix}0 \\ 12 \\ 0\end{matrix} \vert \begin{matrix}0 \\ ⋮ \\ ⋮\end{matrix} ] , [ \begin{matrix}0 \\ 21 \\ 0\end{matrix} \vert \begin{matrix}⋮ \\ 0 \\ ⋮\end{matrix} ] , [ \begin{matrix}0 \\ 6 \\ 0\end{matrix} \vert \begin{matrix}⋮ \\ ⋮ \\ 0\end{matrix} ] \}$$

of the PC-LDPC convolutional code 510 are transmitted to the decoder 600. Accordingly, in the decoder, the received systematic LLR input set 615 is connected (either interleaved when the Z-Shift block 612 is not used, or non-interleaved when the Z-Shift block 612 is used) only to the top Z-MAP decoder set, while the systematic LLR input set 640b-640c to the other two Z-MAP decoders 606b-606c has 0 (undecided value in 2's complement) soft decision input value. The decoding scheduling between the Z-MAP decoders 606a-606c depends on the QC-RSC encoding transmitting order and puncturing. In the code example given in FIG. 16 for final punctured R=1/3, the iterative QC-MAP decoder order can be: Z-MAP0, Z-MAP1, Z-MAP0, Z-MAP2, and so on.

The TQC-LDPC MAP decoder 600 is configured or designed to apply a MAP decoding technique to decode the PC-LDPC convolutional codes described above. Given that in the encoder 500 structure, each RSC encoder 508 is lifted by Z to obtain the Z-RSC encoder set 506, and each Z-RSC encoder set 506 processes the corresponding Z-group systematic bit set at a different quasi-cyclic domain. Similarly, the single bit MAP decoder, explained above, is likewise lifted by Z to obtain the Z-MAP decoder set which consists of Z parallel and independent (i.e., contention-free) single-bit MAP decoders. Each Z-MAP decoder set processes the Z-group encoded LLR set received from the channel at a different quasi-cyclic domain.

Hence, the decoder 600 applies the Z-lifting to the log-likelihood ratio in Equation 13 to derive the Z-MAP decoder set for the received encoded signal with rate R_{base} described above (assuming no puncturing). In Equation 13,Lₐ⁽⁰⁾(uₖ)=0, L_{c}⁽ⁱ⁾⁼⁽4Eₛ/N₀) for all MAP decoders with a systematic input (typically, only one MAP decoder has systematic input), and L_{c}⁽ⁱ⁾=0 for all other MAP decoders that have parity input only.

$$\begin{matrix}{L}_{e}^{( i )} ( {u}_{k} ) = {L}^{( i )} ( {u}_{k} \vert \vec{r} ) - {L}_{c}^{( i )} {r}_{{u}_{k}} - {L}_{a}^{( i )} ( {u}_{k} ) & ( 13 ) \\ = {L}^{( i )} ( {u}_{k} \vert \vec{r} ) - {L}_{c}^{( i )} {r}_{{u}_{k}} - {L}_{e}^{( i - 1 )} ( {u}_{k} ) & ( 13 ) \\ = {\sum }_{t = 0}^{i} {( - 1 )}^{( t )} ( {L}^{( i - t )} ( {u}_{k} \vert \vec{r} ) - {L}_{c}^{( i - t )} {r}_{{u}_{k}} ) & ( 13 )\end{matrix}$$

The decoder 600 uses the same LDPC block code PCM F of either FIGS. 13B-18 with lifting factor Z and J sets of Z rows (namely Z-rows) and B sets of Z systematic columns (namely systematic Z-columns). The row identifiers 502a-502c are based on a specific row of the systematic submatrix of the input 610, namely, H_{z}_{_{sys}}(j,l) j=0, . . . , J−1, l=0, . . . , B−1, which is the systematic part of the j-th Z-row and l-th Z-column of the underlying LDPC block code H. The i-th sub-iteration Z-group LLR output set is defined as L_{z}⁽ⁱ⁾(x_{z}^{(i mod J)}(n)|\vec{r}) and corresponds to the (i mod J)-th H Z-row quasi-cyclic shifted n-th Z-group information bit set encoder input x_{z}^{(i mod J)}(n). The i-th sub-iteration Z-group intrinsic information vector set is defined as L_{cz}⁽ⁱ⁾, where L_{cz}⁽ⁱ⁾=(4Eₛ/N₀)1̅, wherein 1̅ is an all 1 vector of size Z for all the Z-MAP decoders with a systematic input, otherwise L_{cz}⁽ⁱ⁾=0̅, and 0̅ is an all 0 vector. Let Rx_{z}(n) be the n-th received Z-group systematic LLR set corresponding to n-th Z-group information bit set x_{z}(n) in the encoder output. Let L_{ez}⁽ⁱ⁾(x_{z}^{(i mod J)}(n)) be the i-th sub-iteration Z-group extrinsic information set corresponding to x_{z}^{(i mod J)}(n). In the case of non-interleaved systematic transmission, the iterative Z-MAP decoding recursive extrinsic equation for the i-th sub-iteration is expressed by Equation 14 as:

L_{ez}⁽ⁱ⁾(x_{z}^{(i mod J)}(n))H_{z}_{_{sys}}^{-1(T)}(n mod B,i mod J)=Σₜ₌₀ⁱ(−1)^{(t)}(L_{z}^{(i-t)}(x_{z}^{((i-t)mod J)}(n)|\vec{r})H_{z}_{_{sys}}^{-1(T)}(n mod B,(i−t)mod J)−L_{cz}^{(i-t)}Rx_{z}(n)) (14)

In equation 14, H_{z}_{_{sys}}^{-1(T)} is the reverse transpose quasi-cyclic shift matrix such that: H_{z}_{_{sys}}^{-1(T)}(l,j)H_{z}_{_{sys}}^{T}(l,j)=I_{z}, where I_{z} is the z×z identity matrix, and L_{ez}⁽⁰⁾(x_{z}(n))=L_{az}⁽¹⁾(x_{z}(n))=0. Alternatively, in the case of interleaved systematic transmission, the iterative Z-MAP decoding recursive extrinsic equation for the i-th sub-iteration is expressed by Equation 15:

L_{ez}⁽ⁱ⁾(x_{z}^{(i mod J)}(n))H_{z}_{_{sys}}^{-1(T)}(n mod B, i mod J)=Σₜ₌₀ⁱ(−1)^{(t)}(L_{z}^{(i-t)}(x_{z}^{((i-t)mod J)}(n)|\vec{r})−L_{cz}^{(i-t)}Rx_{z}^{((i-t)mod J)}(n))H_{z}_{_{sys}}^{-1(T)}(n mod B, (−t) mod J) (15)

where Rx_{z}^{(i mod J)}(n) is the n-th received Z-group interleaved systematic LLR set. Hence, we can define the recursive iterative relation between the extrinsic LLR information at sub-iteration i and the a priori LLR information at sub-iteration i+l corresponding to Z-group information bit set x_{z}(n), as expressed in Equation (16):

L_{az}⁽ⁱ⁺¹⁾(x_{z}^{((i+1)mod J)}(n))H_{z}_{_{sys}}^{-1(T)}(n mod B, (i+1)mod J)=L_{ez}⁽ⁱ⁾(x_{z}^{(i mod j)}(n))H_{z}_{_{sys}}^{-1(T)}(n mod B, i mod J) (16)

which results in Equation 17:

L_{az}⁽ⁱ⁺¹⁾(x_{z}^{((i+1)mod J)}(n))=L_{ez}⁽ⁱ⁾(x_{z}^{(i mod J)}(n))H_{z}_{_{sys}}^{-1(T)}(n mod B, i mod J) H_{z}_{_{sys}}^{T}(n mod B, (i+1)mod J) (17)

It can be verified that for non-interleaved PCM, where H_{z}_{_{sys}}^{-1(T)}(l,j)=H_{z}_{_{sys}}^{T}(l,j)=I_{z}, the a priori LLR information at sub-iteration i+1 is equal to the extrinsic information at sub-iteration i, as expressed in Equation 18:

L_{az}⁽ⁱ⁺¹⁾(x_{z}^{((i+1)mod J)}(n))=L_{ez}⁽ⁱ⁾(x_{z}^{(i mod J)}(n)) (18)

Equation 18 illustrates that the extrinsic information passing between the Z-MAP decoders 606 during each sub-iteration need to be de-interleaved first, and then re-interleaved prior to processing as a priori information in the next sub-iteration. Finally, the decoder output 635, \hat{x}_{z}⁽ⁱ⁾(n), at the i-th sub-iteration (for interleaved systematic transmission) is expressed by Equation 19:

\hat{x}_{z}⁽ⁱ⁾(n)=L_{z}⁽ⁱ⁾(x_{z}^{(i mod J)}(n)|\vec{r})H_{z}_{_{sys}}^{-1(T)}(n mod B, i mod J)=(Lₑ⁽ⁱ⁾(x_{z}^{(i mod J)}(n))+Lₐ⁽ⁱ⁾(x_{z}^{(i mod J)}(n))+L_{cz}⁽ⁱ⁾Rx_{z}^{(i mod J))}H_{z}_{_{sys}}^{'1(T)}(n mod B, i mod J) (19)

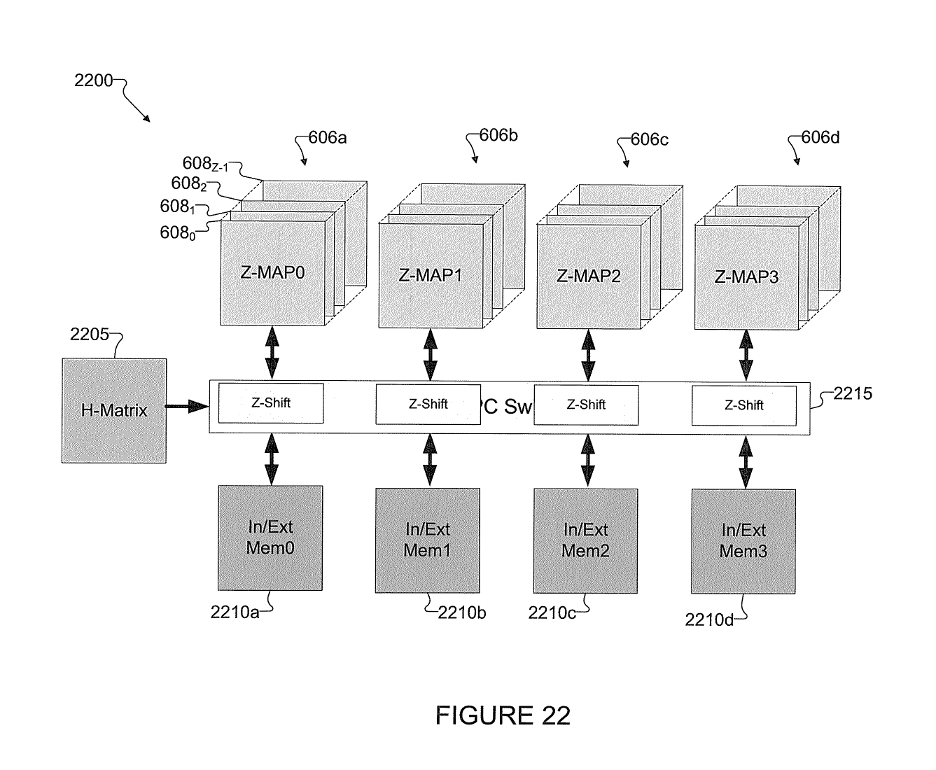

FIG. 22 illustrates a block diagram of a Parallel Processing Z Maximum A posteriori Probability (Z-MAP) decoder 2200 according to this disclosure. The TQC-LDPC MAP decoder 600 of FIG. 6 can include the decoder 2200 or can operate in a similar or same manner as the decoder 2200.

The Z-MAP decoder 2200 includes an H-Matrix 2205, M (for example, λ) Z-MAP decoders 606a-606d, M input/extrinsic memory modules 2210a-2210-d, and a TQC-LDPC switch fabric 2215. In the example shown, the Z-MAP decoder 2200 includes M=4 Z-MAP decoders 606a-606d, representing a Z-MAP decoder per column (for example, λ columns) of the H matrix input 610 to the decoder 2200 (e.g., decoder 600) or output 510 from the encoder 500.

The segmentation methods can also be applied to increase the throughput of overall block/window MAP decoding. The Z-MAP decoder 2200 provides a hierarchical segmentation of the block/window that is divided between multiple MAP decoders 608 working concurrently, wherein each MAP decoder can process one or more segments. Similar to the segmentation method, each of the parallel processing MAP decoders processes different segment of the block at a time thus no contention is occurred during the lambda (λ) memory accesses. The lambda memory can be also divided into segmented memories to support the increased throughput requirement.

The M=4 Z-MAP decoders 606a-606d are connected to the M=4 lambda memory modules 2210a-d through the TQC-LDPC Switch Fabric 2215. The TQC-LDPC Switch Fabric 2215 provides contention-free transfers between the input 610 and extrinsic memory and the Z-MAP decoders 606a-606d. The parity check matrix (namely, H-Matrix) 2205 controls the extrinsic transfers through the switch fabric 2215 in order to provide the contention-free transfers. The TQC-LDPC convolutional code structure fits the contention-free requirement for the parallel processing Z-MAP decoders because in all the interleaved domains (including the non-interleaved domain) the extrinsic information is interleaved only within the quasi-cyclic region (within the size of Z consecutive extrinsic information words). Hence, each Z-MAP decoder 606a-606d and corresponding memory module 2210a-2210d can process a different region of the block/window separately. The only shared memory region required between two consecutive MAP decoders is a (beta) learning period. In certain embodiments, the Parallel Processing Z-MAP decoder 2200 can be optimized such that the TQC-LDPC Switch Fabric 2215 includes M Z-shift registers (such as the Z-Shift 604 or 612), each coupled between a corresponding pair of a Z-MAP decoder 606 and an input/extrinsic memory module 2210 (e.g., Z-MAP0 paired with In/Ext Mem0).

Table 1 summarizes the various algorithms the can be implemented in the decoder 600 and 2200 according to this disclosure. Table 1 includes Log-MAP Decoding based on BCJR algorithm. These decoding algorithms are described above with reference to FIG. 19 and Equations 13-19 and further discussed below.

| Algorithm type | Algorithm expressed Mathematically |
|---|---|
| Log-Likelihood Ratio (LLR) | Equation 20 |
| Forward Path Metric | Equation 23 |
| Backward Path Metric | Equation 24 |
| MAX* Definition | ${{max}_{i}}^{*} ( {x}_{i} ) = ln ( {\sum }_{i} exp ( {x}_{i} ) ) = {x}_{j} + ln ( 1 + {\sum }_{ijay} exp ( - \vert {x}_{i} - {x}_{j} \vert ) ) ,$ |
| | where j = argmaxᵢ(xᵢ) |
| | (as described with reference to Equation 25) |
| MAX* Log-MAP | $L ( {u}_{k} \vert \vec{r} ) = {{max}^{*}}_{( {s}^{′} , s ) \vert {u}_{k} = + 1} ( {α}_{k - 1}^{′} ( {s}^{′} ) + {γ}_{k}^{′} ( {s}^{′} , s ) + {β}_{k}^{′} ( s ) ) - {{max}^{*}}_{( {s}^{′} , s ) \vert {u}_{k} = - 1} ( {α}_{k - 1}^{′} ( {s}^{′} ) + {γ}_{k}^{′} ( {s}^{′} , s ) + {β}_{k}^{′} ( s ) )$ |
| | (as described with reference to Equation 26) |
| MAX Log-MAP | Equation 28 |
| Scaled MAX (SMAX) Log-MAP | ${L}_{e} ( {u}_{k} ) = q ( L ( {u}_{k} \vert \vec{r} ) - {L}_{c} {r}_{{u}_{k}} - {L}_{a} ( {u}_{k} ) )$ |
| (q = 0.75) | Extrinsic Output LLR Intrinsic Apriori |

The Log-MAP decoder [0039] is a trellis-based decoder that processes the received LLR of the encoded bits in both forward and backward directions to generate both the extrinsic information and the LLR of the decoded bits. The extrinsic information can be used for iterative decoding. As an example αₖ₋₁(s′),γₖ(s′, s), and βₖ(s) represent respectively the feed-forward (ff) path metric of bit (k−1) at state s′, the branch metric from state s′ to state s and the feed-backward (fb) path metric of bit (k) at state s. For data transmission over a Additive White Gaussian Noise (AWGN) channel, the Log Likelihood Ratio (LLR) L(uₖ|\vec{r}) of a code bit uₖ=xₖ for a given received AWGN perturbed encoded sequence \vec{r}={. . . , Xₖ, Yₖ⁰, . . . ,Yₖ^{1/R-2}, xₖ₊₁, . . . } (example for 1R∈{3,4,5, . . . }) can be expressed by Equation (20).

$$L ( {u}_{k} \vert \vec{r} ) = ln \frac{{\sum }_{( {s}^{′} , s ) \vert {u}_{k} = + 1}^{ } exp ( {α}_{k - 1}^{′} ( {s}^{′} ) + {γ}_{k}^{′} ( {s}^{′} , s ) + {β}_{k}^{′} ( s ) )}{{\sum }_{( {s}^{′} , s ) \vert {u}_{k} = - 1}^{ } exp ( {α}_{k - 1}^{′} ( {s}^{′} ) + {γ}_{k}^{′} ( {s}^{′} , s ) + {β}_{k}^{′} ( s ) )} \qquad ( 20 )$$

where α′ₖ₋₁, (s′),γ′ₖ(s′,s),β′ₖ(s) are the exponent terms of αₖ₋₁(s′),γₖ(s′,s),βₖ(s), respectively (i.e., α′ₖ₋₁(s′)=In(αₖ₋ₗ(s′))+C where C is dependent on the AWGN variance). The sum in the numerator is over all state transitions s′ to s with a decision uₖ=+1, and the sum in the denominator is over all state transitions s′ to s with a decision uₖ=1. In the case of AWGN, the feed-forward path metric αₖ(s) and the feed-backward path metric βₖ(s) are directly proportional (in LLR calculations all constant terms are eliminated) to the sum of exponents of the candidate path metrics leading to state s from state s′ and state s′′, respectively, as expressed in Equations 21 and 22.

αₖ(s)∝exp(α′ₖ(s))=Σᵢexp(α′ₖ₋₁(sᵢ′)+γ′ₖ(sᵢ′,s)) (21)

βₖ(s)∝exp(β′ₖ(s))=Σᵢexp(β′ₖ₊₁(sᵢ′′)+γ′ₖ(s,sᵢ′′)) (22)

Hence, α′ₖ(s) and β′ₖ(s) can be expressed according to Equations 23 and 24:

α′ₖ(s)=ln(Σᵢexp(α′ₖ₋₁(sᵢ′)+γ′ₖ(s_{i′,}s))) (23)

β′ₖ(s)=ln (Σᵢexp(β′ₖ₊₁(sᵢ′′)+γ′ₖ(s,sᵢ′′))) (24)

The max* operation can be applied to distinguish the maximum path metric from the other candidates in each state. The max* operation is defined according to Equation 25.

max*ᵢ(xᵢ) [symbol] ln(Σᵢ exp(xᵢ))=xⱼ+ln(1+Σ_{i\j}exp(−|xᵢ−xⱼ|)) (25)

where j =argmaxᵢ (xᵢ). The max* operation can be applied to α′ₖ(s) and β′ₖ(s) for all possible sᵢ and sᵢ^{′′}states respectively. The LLR L(uₖ|\vec{r}) of the code bit uₖ as expressed in Equation 20 can be rewritten in max* log-MAP form as expressed in Equation 26.

$$L ( {u}_{k} \vert \vec{r} ) = ln ( {\sum }_{( {s}^{′} , s ) \vert {u}_{k} = + 1}^{ } exp ( {α}_{k - 1}^{′} ( {s}^{′} ) + {γ}_{k}^{′} ( {s}^{′} , s ) + {β}_{k}^{′} ( s ) ) ) - ln ( {\sum }_{( {s}^{′} , s ) \vert {u}_{k} = - 1}^{ } exp ( {α}_{k - 1}^{′} ( {s}^{′} ) + {γ}_{k}^{′} ( {s}^{′} , s ) + {β}_{k}^{′} ( s ) ) ) = {max}_{( {s}^{′} , s ) \vert {u}_{k} = + 1}^{*} ( {α}_{k - 1}^{′} ( {s}^{′} ) + {γ}_{k}^{′} ( {s}^{′} , s ) + {β}_{k}^{′} ( s ) ) - {max}_{( {s}^{′} , s ) \vert {u}_{k} = - 1}^{*} ( {α}_{k - 1}^{′} ( {s}^{′} ) + {γ}_{k}^{′} ( {s}^{′} , s ) + {β}_{k}^{′} ( s ) ) \qquad ( 26 )$$

Alternatively, the max operation can be employed in order to reduce the max* operation complexity by finding only the maximum path metric of all candidates in each state as expressed in Equation 27.

maxᵢ(xᵢ)=xᵢ (27)

where, again, j=argmaxᵢ (xᵢ). The max operation can be applied to to α′ₖ(s) and β′ₖ(s) for all possible sᵢ′ and sᵢ^{′′}states, respectively. The LLR of the code bit uₖ can then be written in max Log-MAP form as expressed in Equation 28:

L(uₖ|\vec{r})=max _{s′,s)|u}_{ₖ}_{⁼⁺¹}(α′ₖ₋₁(s′)+γ′ₖ(s′, s)+β′ₖ(s))−max_{s′,s)|u}_{ₖ}_{^{=−1}}(α′ₖ₋₁(s′)+γ′ₖ(s′,s)+β′ₖ(s)) (28)

As mentioned above, the max operation has lower complexity than the max* operation, since the max operation excludes the correction function (10) that is typically implemented as a Look-Up Table (LUT). However, the reduced complexity of the max operation results in a higher BER/FER (˜0.4-0.5 dB degradation). See REF6 and REF7. In REF6 a scaling factor q scales the extrinsic information values after each iteration, to mitigate the BER increase that occurs due to employing max operation (namely Scaled MAX Log-MAP) instead of the max* operation. Hence, the Scaled MAX Log-MAP extrinsic information LLR can be written as expressed in Equation 29:

Lₑ(uₖ)=q(L(uₖ|\vec{r})−L_{c}rᵤ_{ₖ}−Lₐ(uₖ)) (29)

where Lₐ(uₖ) is the a priori LLR of uₖ (for example, an a priori information from previous iteration extrinsic information), rᵤ_{ₖ} is the received input systematic bit k and L_{c}rᵤ_{ₖ}=(4Eₛ/N₀)rᵤ_{ₖ} is the intrinsic information. In REF6 it is shown that q=0.7 provides less than 0.2 dB SNR degradation to maintain the same BER and Block Error Rate (BLER) as the Log-MAP. As an example, q=0.75 can selected or employed since it can be implemented using right shifts and addition operations instead of multiplications.

The branch metric γ′ₖ(s′, s) can be written using the LLR expressions as in expressed in equation (30). (See REF7).

$${γ}_{k}^{′} ( {s}^{′} , s ) = \frac{1}{2} {\hat{u}}_{k} {L}_{a} ( {u}_{k} ) + \frac{1}{2} {L}_{c} {\vec{r}}_{k} \cdot {\vec{v}}_{k} \qquad ( 30 )$$

where \vec{r}ₖ is the received input symbol (systematic and parity) vector, and \vec{v}ₖ and ûₖ are the expected encoder output symbol (systematic and parity bits) vector and expected systematic bit respectively for transition from state s′ to state s.

Accordingly, MAP decoding enables an iterative process. An iteration is defined as a processing cycle through a set of (non-repetitive) MAP decoders. A sub-iteration is defined as a processing cycle through a single MAP decoder within the set. Let i be one less than the number of sub-iterations, and consider q=1 with the apriori information at sub-iteration i equals the extrinsic information at sub-iteration i−1, Lₐ⁽ⁱ⁾(uₖ)=Lₑ^{(i-1 )}(uₖ). Hence, the general (non-interleaved) iterative MAP decoding recursive extrinsic equation for the i-th sub-iteration is expressed in Equation 13 (described above).

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A method of encoding, the method comprising:
receiving input systematic data including an input group (x_{z}(n)) of Z systematic bits.
generating a Low Density Parity Check (LDPC) base code using the input group (x_{z}(n)), wherein the LDPC base code is characterized by a row weight (Wr), a column weight (Wc), and a first level lifting factor (Z).
transforming the LDPC base code into a Trellis-based Quasi-Cyclic LDPC (TQC-LDPC) convolutional code;
generating, by Trellis-based Quasi-Cyclic LDPC Recursive Systematic Convolutional (QC-RSC) encoder processing circuitry using the TQC-LDPC convolutional code, a Parallel Concatenated Trellis-based Quasi-Cyclic LDPC (PC-LDPC) convolutional code in a form of an H-matrix including a systematic submatrix (H_{sys}) of the input systematic data and a parity check submatrix (Hₚₐᵣ) of parity check bits, wherein the Hₚₐᵣ includes a column of Z-group parity bits;
concatenating the Hₚₐᵣ with each column of systematic bits, wherein the Hₚₐᵣ includes J parity bits per systematic bit.

2. The method of claim 1, wherein the LDPC base code is a Spatially-Coupled LDPC (SC-LDPC) base code.

3. The method of claim 1, wherein the column of parity bits includes multiple rows of parity bits, yielding a rate less than one-half (R<½).

4. The method of claim 1, wherein a rate of the TQC-LDPC Convolutional code is increased by a puncturing operation.

5. The method of claim 1, wherein each QC-RSC includes J Z-RSC encoders, and each Z-RSC encoder includes Z identical RSC encoders, wherein each RSC encoder encodes a one of the Z input bits it at a time.

6. The method of claim 1, further comprising reducing periodicity and bit error rate (BER) of the code by increasing a size (B) of the a systematic submatrix (H_{sys}).

7. The method of claim 1, further comprises applying a second level of Zp cyclic shifts to the H-matrix according to a Dual-Step QC Shift method, wherein Zp represents a second level lifting factor over the lifting factor Z, and wherein N represents a base-family code length.

8. The method of claim 1, further comprising modifying quasi-cyclic values of a Trellis-based Quasi-Cyclic LDPC (TQC-LDPC) convolutional code to increase bit error rate performance of a decoder that receives the PC-LDPC convolutional code.

9. The method of claim 1, further comprising:
selecting a reference row in which all shift entries denote a unity matrix;
shifting each other row in the TQC-LDPC convolutional code relative to the reference row.

10. An encoder comprising:
Trellis-based Quasi-Cyclic LDPC Recursive Systematic Convolutional (QC-RSC) encoder processing circuitry configured to:
receive input systematic data including an input group (x_{z}(n)) of Z systematic bits.
generate a Low Density Parity Check (LDPC) base code using the input group (x_{z}(n)), wherein the LDPC base code is characterized by a row weight (Wr), a column weight (Wc), and a first level lifting factor (Z);
transform the LDPC base code into a Trellis-based Quasi-Cyclic LDPC (TQC-LDPC) convolutional code.
generate a Parallel Concatenated Trellis-based Quasi-Cyclic LDPC (PC-LDPC) convolutional code in a form of an H-matrix including a systematic submatrix (H_{sys}) of the input systematic data and a parity check submatrix (Hₚₐᵣ) of parity check bits, wherein the Hₚₐᵣ , includes a column of Z-group parity bits;
concatenate the Hₚₐᵣ with each column of systematic bits, wherein the Hₚₐᵣ includes J parity bits per systematic bit.

11. The encoder of claim 10, wherein the LDPC base code is a Spatially-Coupled LDPC (SC-LDPC) base code.

12. The encoder of claim 10, wherein the column of parity bits includes multiple rows of parity bits, yielding a rate less than one-half (R<½).

13. The encoder of claim 10, wherein the QC-RSC encoder processing circuitry is further configured to: increase a rate of the TQC-LDPC Convolutional code by performing a puncturing operation.

14. The encoder of claim 10, wherein each QC-RSC includes J Z-RSC encoders, and each Z-RSC encoder includes Z identical RSC encoders, wherein each RSC encoder encodes a one of the Z input bits it at a time.

15. The encoder of claim 10, wherein the QC-RSC encoder processing circuitry is further configured to: reduce periodicity and bit error rate (BER) of the code by increasing a size (B) of the a systematic submatrix (H_{sys}).

16. The encoder of claim 10, wherein the QC-RSC encoder processing circuitry is further configured to: apply a second level of Zp cyclic shifts to the H-matrix according to a Dual-Step QC Shift encoder, wherein Zp represents a second level lifting factor over the lifting factor Z, and wherein N represents a base-family code length.

17. The encoder of claim 10, wherein the QC-RSC encoder processing circuitry is further configured to: modify quasi-cyclic values of a Trellis-based Quasi-Cyclic LDPC (TQC-LDPC) convolutional code to increase bit error rate performance of a decoder that receives the PC-LDPC convolutional code.

18. The encoder of claim 10, wherein the QC-RSC encoder processing circuitry is further configured to:
select a reference row in which all shift entries denote a unity matrix;
shift each other row in the TQC-LDPC convolutional code relative to the reference row.

19. A decoder comprising:
Trellis-based Quasi-Cyclic Low Density Parity Check (TQC-LDPC) Maximum A posteriori Probability (MAP) decoder processing circuitry configured to:
receive a Parallel Concatenated Trellis-based Quasi-Cyclic LDPC (PC-LDPC) convolutional code in a form of an H-matrix including a systematic submatrix (H_{sys}) of the input systematic data and a parity check submatrix (Hₚₐᵣ) of parity check bits, wherein the PC-LDPC convolutional code is characterized by a lifting factor (Z), the Hₚₐᵣ includes a column of Z-group parity bits concatenated with each column of systematic bits, and the Hₚₐᵣ includes J parity bits per systematic bit;
decode the PC-LDPC convolutional code into and a group (x_{z}(n)) of Z systematic bits by, for each Z-row of the PC-LDPC convolutional code:
determining, from the PC-LDPC convolutional code, a specific quasi-cyclical domain of the Z-row that is different from any other quasi-cyclical domain of another Z-row of the PC-LDPC convolutional code,
quasi-cyclically shifting the bits of the Z-row by the specific quasi-cyclical domain;
performing Z parallel MAP decoding processes on the shifted bits of the Z-row, and
unshifting the parallel decoded bits of the Z-row by the specific quasi-cyclical domain, yielding the group (x_{z}(n)) of Z systematic bits.

20. The decoder of claim 19, wherein the TQC-LDPC MAP decoder processing circuitry is further configured to: omit quasi-cyclically shifting the bits of a first Z-row based on a determination that the first Z-row is all cyclical shifts of zero.

21. The decoder of claim 19, wherein decoding the PC-LDPC convolutional code into and a group (x_{z}(n)) of Z systematic bits comprises applying a MAX* Log MAP decoding algorithm.

22. The decoder of claim 19, wherein decoding the PC-LDPC convolutional code into and a group (x_{z}(n)) of Z systematic bits comprises applying a MAX Log MAP decoding algorithm.
